(19) United States
(12) Patent Application Publication
(10) Pub. No.: US 2026/0123137 A1
(43) Pub. Date: Apr. 30, 2026

(54) DISPLAY DEVICE AND ELECTRONIC DEVICE INCLUDING THE SAME

(71) Applicant: Samsung Display Co., LTD., Yongin-si (KR)

(72) Inventors: Hyungil JEON, Yongin-si (KR); Gyujeong LEE, Yongin-si (KR); Changil TAE, Yongin-si (KR)

(21) Appl. No.: 19/180,610

(22) Filed: Apr. 16, 2025

(30) Foreign Application Priority Data
Oct. 25, 2024 (KR) 10-2024-0147864

(51) Int. Cl. H10H 29/49; H01L 25/16; H10H 29/01; H10H 29/03

(52) U.S. Cl. CPC H10H 29/49; H10H 29/012; H10H 29/03; H10W 90/00

(57) ABSTRACT

A display device includes a substrate, a first pixel driving circuit part and a second pixel driving circuit part, disposed on the substrate to be spaced apart from each other, a first pad part disposed on the first pixel driving circuit part to be electrically connected to the first pixel driving circuit part, a second pad part disposed on the second pixel driving circuit part to be electrically connected to the second pixel driving circuit part, a first layer disposed on the first pad part and the second pad part to cover each of the first pad part and the second pad part, and a first inorganic light-emitting diode disposed on the first layer to be electrically connected to the first pad part.

This application claims priority to Korean Patent Application No. 10-2024-0147864, filed on Oct. 25, 2024, and all the benefits accruing therefrom under 35 U.S.C. § 119, the content of which in its entirety is herein incorporated by reference.

### BACKGROUND

### 1. Field

Embodiments relate to a display device, and more particularly, to a flexible display device.

### 2. Description of the Related Art

According to the development of display devices visually displaying electrical signals, various display devices having excellent characteristics such as reduced thickness, reduced weight, and relatively low power consumption, have been introduced. For example, flexible display devices that may be folded or rolled into a roll shape have been introduced. Recently, research and development on display devices having various structures, such as stretchable display devices that may be changed into various shapes, have been actively conducted.

### SUMMARY

Embodiments include a display device, e.g., a flexible display device. However, these objectives are exemplary, and the scope of the disclosure is not limited thereto.

Additional features will be set forth in part in the description which follows and, in part, will be apparent from the description, or may be learned by practice of the presented embodiments of the disclosure.

In embodiment of the disclosure, a display device includes a substrate, a first pixel driving circuit part and a second pixel driving circuit part, which are disposed on the substrate to be spaced apart from each other, a first pad part disposed on the first pixel
driving circuit part to be electrically connected to the first pixel driving circuit part, a second pad part disposed on the second pixel driving circuit part to be electrically connected to the second pixel driving circuit part, a first layer disposed on the first pad part and the second pad part to cover each of the first pad part and the second pad part, a first inorganic light-emitting diode disposed on the first layer to be electrically connected to the first pad part, a second layer disposed on the first layer to cover the first inorganic light-emitting diode, and a second inorganic light-emitting diode disposed on the second layer to be electrically connected to the second pad part.

In an embodiment, the display device may further include a first connection part accommodated in a first connection opening to electrically connect the first pad part and the first inorganic light-emitting diode to each other, the first connection opening penetrating the first layer.

In an embodiment, the display device may further include a second connection part accommodated in a second connection opening to electrically connect the second pad part and the second inorganic light-emitting diode to each other, the second connection opening penetrating each of the first layer and the second layer.

In an embodiment, a height of the second inorganic light-emitting diode from the substrate may be greater than a height of the first inorganic light-emitting diode from the substrate.

In an embodiment, the display device may further include a third pixel driving circuit part disposed on the substrate, a third pad part disposed on the third pixel driving circuit part to be electrically connected to the third pixel driving circuit part, a third layer disposed on the second layer to cover the second inorganic light-emitting diode, and a third inorganic light-emitting diode disposed on the third layer to be electrically connected to the third pad part.

In an embodiment, the display device may further include a third connection part accommodated in a third connection opening to electrically connect the third pad part and the third inorganic light-emitting diode to each other, the third connection opening penetrating each of the first layer, the second layer, and the third layer.

In an embodiment, the display device may further include a fourth layer disposed on the third layer to cover the third inorganic light-emitting diode.

In an embodiment, a height of the third inorganic light-emitting diode from the substrate may be greater than a height of the second inorganic light-emitting diode from the substrate.

In an embodiment, the first inorganic light-emitting diode and the second inorganic light-emitting diode may emit light of different colors from each other.

In an embodiment of the disclosure, an electronic device includes a substrate, a first pixel driving circuit part, a second pixel driving circuit part, and a third pixel driving circuit part, which are disposed on the substrate to be spaced apart from each other, a first pad part disposed on the first pixel driving circuit part to be electrically connected to the first pixel driving circuit part, a second pad part disposed on the second pixel driving circuit part to be electrically connected to the second pixel driving circuit part, a third pad part disposed on the third pixel driving circuit part to be electrically connected to the third pixel driving circuit part, a first layer disposed on the first pad part, the second pad part, and the third pad part to cover each of the first pad part, the second pad part, and the third pad part, a first inorganic light-emitting diode disposed on the first layer to be electrically connected to the first pad part, a second layer disposed on the first layer to cover the first inorganic light-emitting diode, a second inorganic light-emitting diode disposed on the second layer to be electrically connected to the second pad part, a third layer disposed on the second layer to cover the second inorganic light-emitting diode, and a third inorganic light-emitting diode disposed on the third layer to be electrically connected to the third pad part.

In an embodiment of the disclosure, a method of manufacturing a display device includes disposing a first pixel driving circuit part and a second pixel driving circuit part on a substrate, disposing a first pad part on the first pixel driving circuit part to be electrically connected to the first pixel driving circuit part, disposing a second pad part on the second pixel driving circuit part to be electrically connected to the second pixel driving circuit part, disposing a first layer on the first pad part and the second pad part to cover each of the first pad part and the second pad part, transferring a first inorganic light-emitting diode onto the first pad part, disposing a second layer on the first layer to cover the first inorganic light-emitting diode, and transferring a second inorganic light-emitting diode onto the second pad part.

In an embodiment, the transferring the first inorganic light-emitting diode may include disposing the first inorganic light-emitting diode on a first wafer, disposing the first inorganic light-emitting diode on the first layer so that the first inorganic light-emitting diode is electrically connected to the first pad part, and removing the first wafer from the first inorganic light-emitting diode.

In an embodiment, the transferring the second inorganic light-emitting diode may include disposing the second inorganic light-emitting diode on a second wafer, disposing the second inorganic light-emitting diode on the second layer so that the second inorganic light-emitting diode is electrically connected to the second pad part, and removing the second wafer from the second inorganic light-emitting diode.

In an embodiment, the first wafer may be different from the second wafer.

In an embodiment, the method may further include forming a first connection opening in the first layer to expose the first pad part, and disposing the first connection part including a conductive material in the first connection opening, and the first connection part may electrically connect the first pad part and the first inorganic light-emitting diode to each other.

In an embodiment, the method may further include forming a second connection opening in the first layer and the second layer to expose the second pad part, and disposing a second connection part including a conductive material in the second connection opening, and the second connection part may electrically connect the second pad part and the second inorganic light-emitting diode to each other.

In an embodiment, the method may further include disposing a third pixel driving circuit part on the substrate, disposing a third pad part on the third pixel driving circuit part to be electrically connected to the third pixel driving circuit part, disposing a third layer on the second layer to cover the second inorganic light-emitting diode, and transferring a third inorganic light-emitting diode onto the third pad part, and the transferring the third inorganic light-emitting diode may include disposing the third inorganic light-emitting diode on a third wafer, disposing the third inorganic light-emitting diode on the third layer so that the third inorganic light-emitting diode is electrically connected to the third pad part, and removing the third inorganic light-emitting diode from the third wafer.

In an embodiment, the method may further include disposing a fourth layer on the third layer to cover the third inorganic light-emitting diode.

The method may further include forming a third connection opening in the first layer, the second layer, and the third layer to expose the third pad part, and disposing a third connection part including a conductive material in the third connection opening, and the third connection part may electrically connect the third pad part and the third inorganic light-emitting diode to each other.

In an embodiment, a height of the first inorganic light-emitting diode from the substrate, a height of the second inorganic light-emitting diode from the substrate, and a height of the third inorganic light-emitting diode from the substrate may sequentially increase.

Other features and advantages other than those described above will now become apparent from the following drawings, claims, and the detailed description of the disclosure.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic perspective view of an embodiment of a display device;

FIGS. 2A and 2B are perspective views each illustrating a state in which the display device of FIG. 1 is stretched in a first direction;

FIG. 2C is a perspective view illustrating a state in which the display device of FIG. 1 is stretched in a second direction;

FIG. 2D is a perspective view illustrating a state in which the display device of FIG. 1 is stretched in the first direction and the second direction;

FIG. 2E is a perspective view illustrating a state in which the display device of FIG. 1 is stretched in a third direction;

FIG. 3 is a schematic plan view of an embodiment of a display device;

FIG. 4A is an enlarged plan view of an embodiment of a region IV of FIG. 3 as a portion of the display device of FIG. 3;

FIG. 4B is an enlarged plan view of an embodiment of the region IV of FIG. 3 as a portion of the display device of FIG. 3;

FIG. 4C is an enlarged plan view of an embodiment of the region IV of FIG. 3 as a portion of the display device of FIG. 3;

FIG. 5 is a schematic cross-sectional view of an embodiment of a first island portion and a first bridge portion, which are disposed in a display area of a display device;

FIGS. 6A to 6C are equivalent circuit diagrams each illustrating an embodiment of a sub-pixel of a display device;

FIG. 7A is a schematic cross-sectional view of an embodiment of a light-emitting element of a display device;

FIG. 7B is a schematic cross-sectional view of an embodiment of a light-emitting element of a display device;

FIG. 8A is an enlarged plan view of an embodiment of a first island portion of a display device;

FIG. 8B is a plan view schematically illustrating an embodiment of an arrangement of lines on a first bridge portion of a display device;

FIG. 9 shows schematic cross-sectional views of a display device, taken along line I-I′ of FIG. 8A and a line II-II′ of FIG. 8B, respectively;

FIGS. 10A and 10B are schematic flowcharts each illustrating an embodiment of a method of manufacturing a display device;

FIGS. 11 to 17 are schematic cross-sectional views of an embodiment of a display device; and

FIGS. 18A to 18G are schematic perspective views respectively showing embodiments of an electronic device including a display device.

### DETAILED DESCRIPTION

Reference will now be made in detail to embodiments, embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus their description will not be repeated.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the disclosure, and are not intended to preclude the possibility that one or more other features or elements may exist or may be added.

It will be understood that when a layer, region, or element is referred to as being formed on another layer, region, or element, it may be directly or indirectly formed on the other layer, region, or element. That is, for example, intervening layers, regions, or elements may be present.

Sizes of elements in the drawings may be exaggerated for convenience of explanation. In other words, since sizes and thicknesses of components in the drawings are arbitrarily illustrated for convenience of explanation, the following embodiments are not limited thereto.

The x-axis, the y-axis, and the z-axis are not limited to three axes on the orthogonal coordinates system, and may be interpreted in a broad sense including the same. For example, the x-axis, the y-axis, and the z-axis may be perpendicular to one another, or may represent different directions that are not perpendicular to one another.

When an illustrative embodiment may be implemented differently, a predetermined process order may be performed differently from the described order. For example, two consecutively described processes may be performed substantially at the same time or performed in an order opposite to the described order.

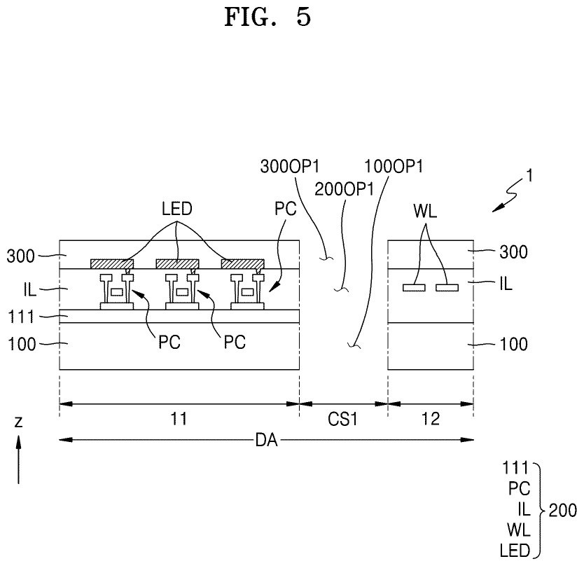

In the disclosure, “in a plan view” means a plan view viewed in a direction perpendicular to a substrate 100 (refer to FIG. 5). That is, “A and B are spaced apart from each other in a plan view” means “A and B are spaced apart from each other when viewed in a direction perpendicular to the substrate 100 (refer to FIG. 5).”

In the disclosure, “in a cross-sectional view” means a plan view cut in a direction perpendicular to the substrate 100 (refer to FIG. 5). That is, “A and B are spaced apart from each other in a cross-sectional view” means “A and B are spaced apart from each other in a plan view cut in a direction perpendicular to the substrate 100 (refer to FIG. 5).”

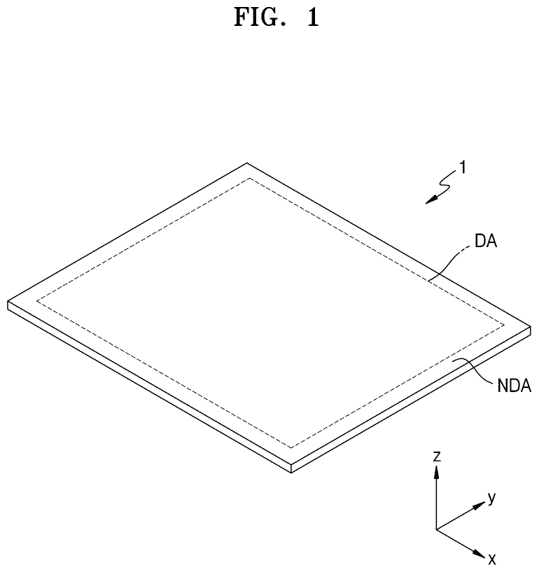

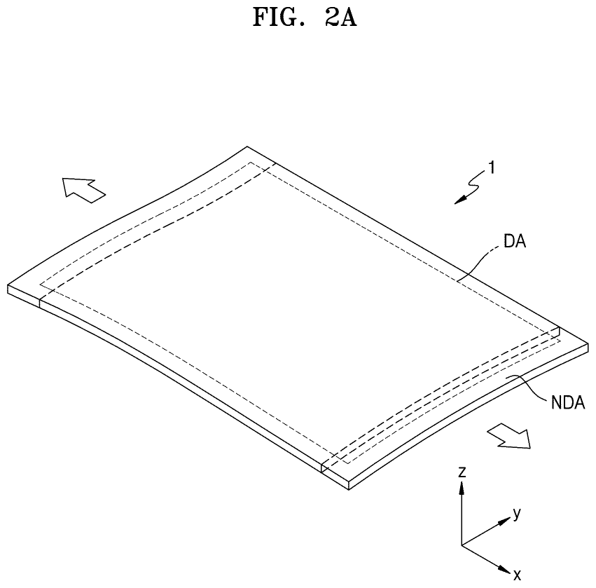

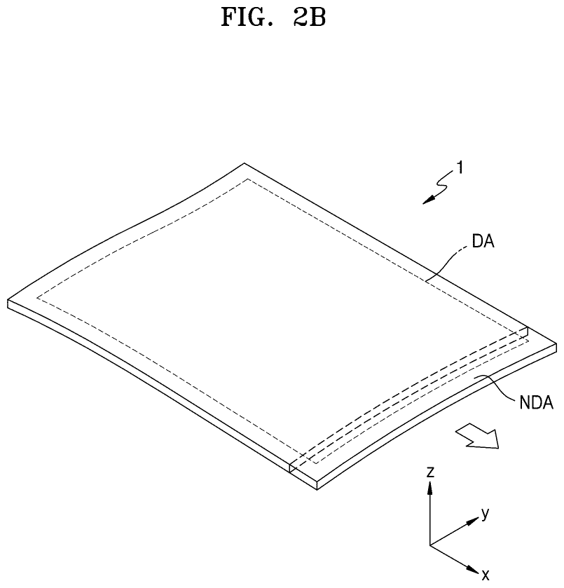

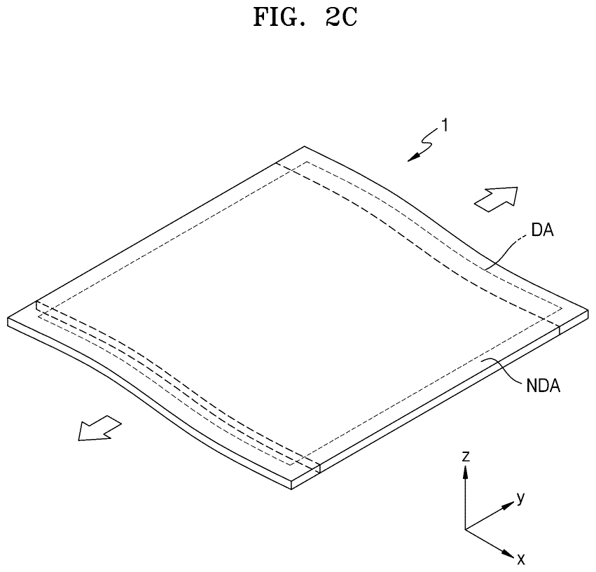

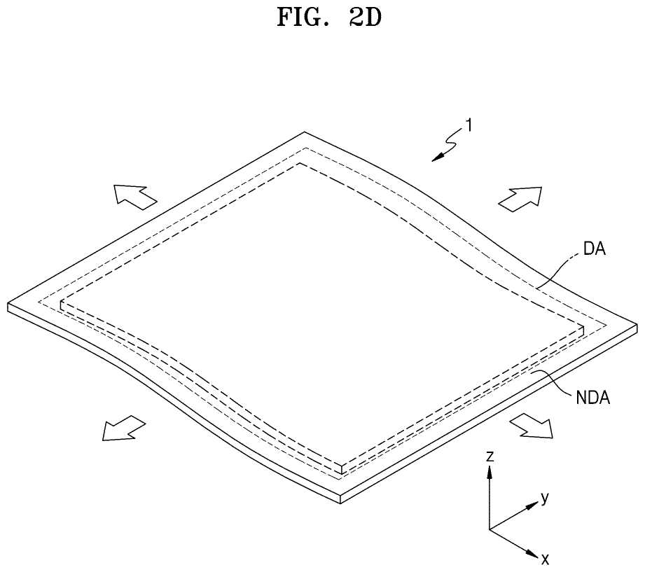

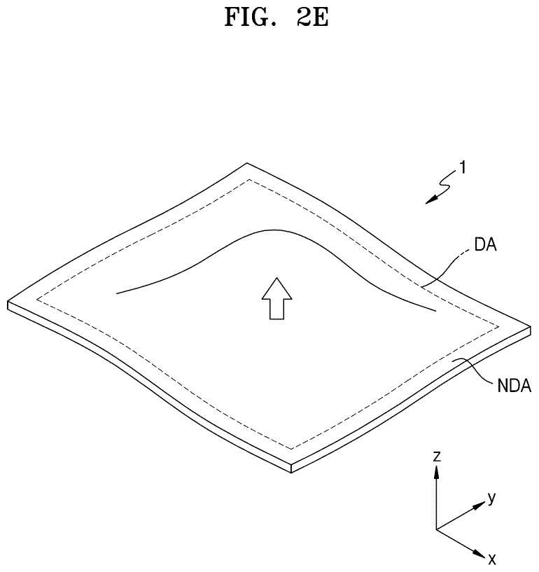

FIG. 1 is a schematic perspective view of an embodiment of a display device 1. FIGS. 2A and 2B are perspective views each illustrating a state in which the display device 1 of FIG. 1 is stretched in a first direction (e.g., an x direction and/or an -x direction). FIG. 2C is a perspective view illustrating a state in which the display device 1 of FIG. 1 is stretched in a second direction (e.g., a y direction and/or a -y direction). FIG. 2D is a perspective view illustrating a state in which the display device 1 of FIG. 1 is stretched in the first direction (e.g., the x direction and/or the -x direction) and the second direction (e.g., the y direction and/or the -y direction). FIG. 2E is a perspective view illustrating a state in which the display device 1 of FIG. 1 is stretched in a third direction (e.g., a z direction and/or a -z direction).

Referring to FIG. 1, the display device 1 may include a display area DA and a non-display area NDA. The display area DA may include a plurality of pixels. The display device 1 may provide an image by light emitted by the plurality of pixels. The non-display area NDA may be disposed outside the display area DA. The non-display area NDA may surround an entirety of the display area DA.

The display device 1 may be stretched or shrunk in various directions. The display device 1 may be stretched in the first direction (e.g., the x direction and/or the -x direction) by an external force applied by an external object of a user. In an embodiment, as shown in FIGS. 2A and 2B, the display area DA and/or the non-display area NDA of the display device 1 may be stretched in the first direction (e.g., the x direction and/or the -x direction). In an embodiment, as shown in FIG. 2A, the display device 1 may be stretched in the x direction and the -x direction, or the display device 1 may be stretched in the x direction in a state in which one side of the display device 1 is fixed, as shown in FIG. 2B, for example.

The display device 1 may be stretched in the second direction (e.g., a y direction and/or a -y direction) by an external force applied by an external object or a user. In an embodiment, as shown in FIG. 2C, the display area DA and/or the non-display area NDA of the display device 1 may be stretched in the y direction and the -y direction. In another embodiment, the display device 1 may be stretched in the y direction or the -y direction in a state in which one side of the display device 1 is fixed.

The display device 1 may be stretched in a plurality of directions, e.g., the first direction (e.g., the x direction and/or the -x direction) and the second direction (e.g., the y direction and/or the -y direction), by an external force applied by an external object or a part of a human's body. As shown in FIG. 2D, the display area DA and/or the non-display area NDA of the display device 1 may be stretched in the ±x direction and the ±y direction.

The display device 1 may be stretched in the third direction (e.g., the z direction or the -z direction) by an external force applied by an external object or a part of a human's body. In an embodiment, FIG. 2E shows that a portion of the display device 1, e.g., a partial area of the display area DA, protrudes in the z direction. In another embodiment, a portion of the display device 1, e.g., a partial area of the display area DA, may protrude in the -z direction (or may be depressed in the z direction).

FIGS. 2A to 2E show that the display device 1 is stretched in the first direction, the second direction, and/or the third direction, but the disclosure is not limited thereto. In another embodiment, the display device 1 may be variously modified into irregular shapes, such as having two or more axes and being bent or twisted.

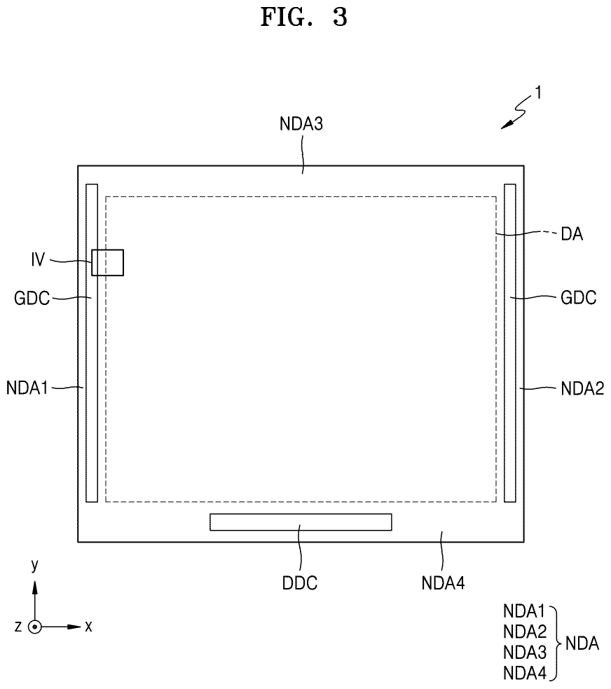

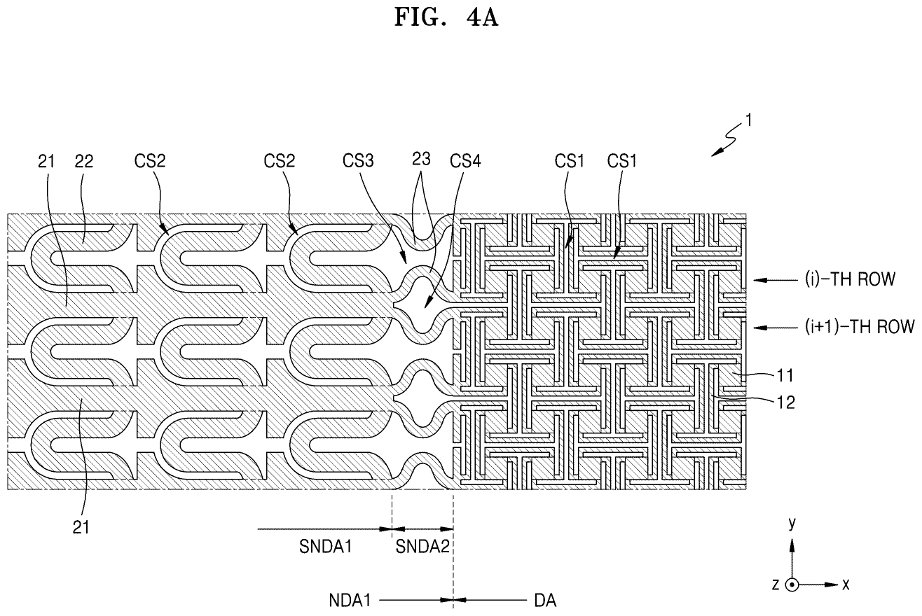

FIG. 3 is a schematic plan view of an embodiment of the display device 1.

A plurality of pixels may be disposed in the display area DA of the display device 1. Each of the plurality of pixels may include sub-pixels emitting different colors of light. A light-emitting element corresponding to each sub-pixel may be disposed in the display area DA. A circuit configured to provide electrical signals to the light-emitting elements disposed in the display area DA and transistors electrically connected to the light-emitting elements may be disposed in the non-display area NDA surrounding the display area DA. Gate driving circuits GDC may be respectively disposed in a first non-display area NDA1 and a second non-display area NDA2, wherein the first non-display area NDA1 and the second non-display area NDA2 are disposed on opposite sides of the display device with the display area DA therebetween. A gate driving circuit GDC may include drivers configured to provide electrical signals to a gate electrode of each of the transistors electrically connected to the light-emitting elements. FIG. 3 shows that the gate driving circuit GDC is disposed in each of the first non-display area NDA1 and the second non-display area NDA2, but the disclosure is not limited thereto. In another embodiment, the gate driving circuit GDC may be disposed in any one of the first non-display area NDA1 and the second non-display area NDA2.

A data driving circuit DDC may be disposed in a third non-display area NDA3 and/or a fourth non-display area NDA4, which connects the first non-display area NDA1 to the second non-display area NDA2. In an embodiment, FIG. 3 shows that the data driving circuit DDC is disposed in the fourth non-display area NDA4. In another embodiment, the data driving circuit DDC may be disposed in each of the third non-display area NDA3 and the fourth non-display area NDA4.

FIG. 3 shows that the data driving circuit DDC is disposed in the fourth non-display area NDA4 of the display device 1, but the disclosure is not limited thereto. In another embodiment, the display device 1 may further include a flexible circuit board (not shown) electrically connected to a terminal portion (not shown) disposed in the fourth non-display area NDA4, and the data driving circuit DDC may be disposed on the flexible circuit board described above.

In some embodiments, the elongation rate of the non-display area NDA may be equal to or less than the elongation rate of the display area DA. In an embodiment, the non-display area NDA may have a different elongation rate for each area. In an embodiment, the first non-display area NDA1, the second non-display area NDA2, and the third non-display area NDA3 may have substantially the same elongation rate, but the elongation rate of the fourth non-display area NDA4 may be less than the elongation rate of each of the first non-display area NDA1, the second non-display area NDA2, and the third non-display area NDA3, for example.

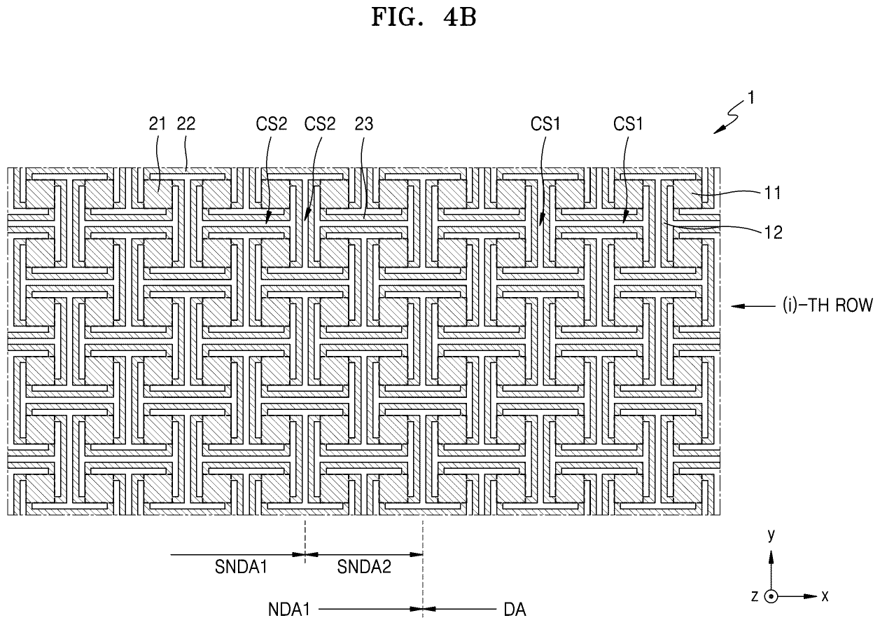

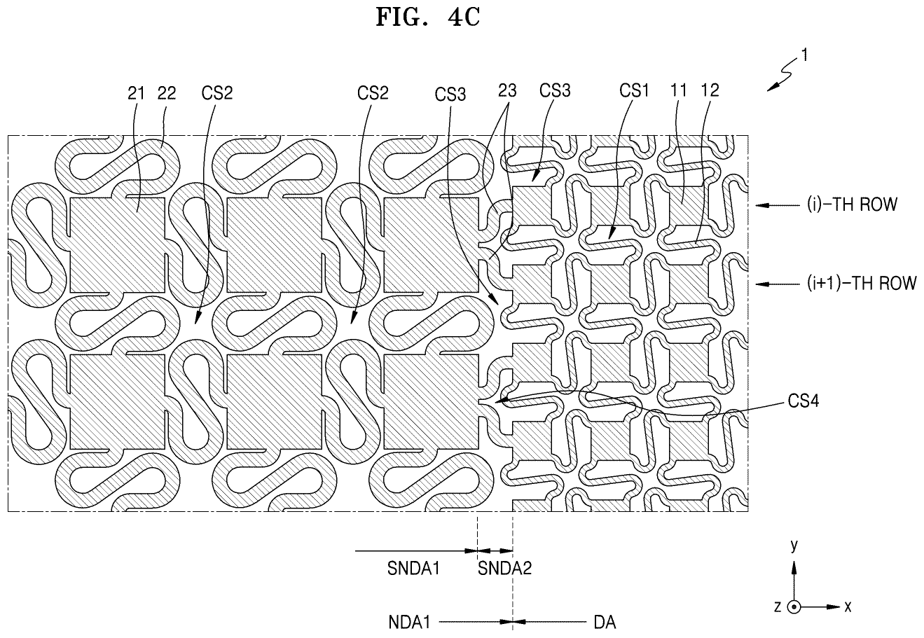

FIG. 4A is an enlarged plan view of an embodiment of a region IV of FIG. 3, which is a portion of the display device 1.

Referring to FIG. 4A, the display device 1 may include, in the display area DA, first island portions 11 spaced apart from each other in the first direction (e.g., the x direction or the -x direction) and the second direction (e.g., the y direction or the -y direction), and first bridge portions 12 connecting neighboring (adjacent) first island portions 11 to each other.

Each first island portion 11 may be connected to a plurality of first bridge portions 12. In an embodiment, each first island portion 11 may be connected to four first bridge portions 12, for example. Two first bridge portions 12 may be respectively disposed on opposite sides of the first island portion 11 in the first direction (e.g., the x direction or the -x direction), and the remaining two bridge portions 12 may be respectively disposed on opposite sides of the first island portion 11 in the second direction (e.g., the y direction or the -y direction). In an embodiment, the four first bridge portions 12 may be respectively connected to four sides of the first island portion 11. Each of the four first bridge portions 12 may be next (adjacent) to each of corners of the first island portion 11.

The first bridge portions 12 may be spaced apart from each other by a first opening area CS1 defined between the first bridge portions 12. In an embodiment, a first opening area CS1 having an approximately H shape and a first opening area CS1 having an approximately I shape obtained by rotating the above described H shape by 90 degrees may be alternately and repeatedly arranged in each of the first direction (e.g., the x direction or the -x direction) and the second direction (e.g., the y direction or the -y direction). Both end portions of each first bridge portion 12 are respectively connected to neighboring (adjacent) first island portions 11, but one side of each first bridge portion 12 may be spaced apart from one side of a neighboring (adjacent) first island portion 11 and/or one side of another first bridge portion 12 by the first opening area CS1.

The display device 1 may include, in a non-display area, e.g., the first non-display area NDA1 shown in FIG. 4A, second island portions 21 spaced apart from each other and second bridge portions 22 connecting neighboring (adjacent) second island portions 21 to each other.

Each second island portions 21 may extend in the first direction (e.g., the x direction or the -x direction). The second island portions 21 may be spaced apart from each other in the second direction (e.g., the y direction or the -y direction) crossing the first direction (e.g., the x direction or the -x direction). Each second island portion 21 may include drivers of the gate driving circuit GDC (refer to FIG. 3) described above with reference to FIG. 3.

A second bridge portion 22 may have a serpentine shape. A length of the second bridge portion 22 may be greater than the shortest distance between neighboring (adjacent) second island portions 21 in the second direction (e.g., the y direction or the -y direction). In an embodiment, the second bridge portion 22 may have an approximately omega (Ω) shape that is convex toward the first direction (e.g., the x direction or the -x direction). The second bridge portions 22 may be disposed between neighboring (adjacent) second island portions 21 and may be spaced apart from each other.

The second bridge portions 22 between neighboring (adjacent) second island portions 21 may be spaced apart from each other by a second opening area CS2. Second opening area s CS2 and the second bridge portions 22 may be alternately arranged in the first direction (e.g., the x direction or the -x direction) between neighboring (adjacent) second island portions 21. The second opening areas CS2 may have the same shape. Both end portions of each second bridge portion 22 are respectively connected to neighboring (adjacent) second island portions 21, but one side of each second bridge portion 22 may be spaced apart from one side of a neighboring (adjacent) second island portion 21 and/or one side of another second bridge portion 22 by the second opening area CS2.

Any one second island portion 21 disposed in the first non-display area NDA1 may correspond to the first island portions 11 of a plurality of rows arranged in the display area DA. In an embodiment, any one second island portion 21 disposed in the first non-display area NDA1 may correspond to the first island portions 11 arranged in an (i)-th row and the first island portions 11 arranged in an (i+1)-th row in the display area DA (where i is a positive number greater than 0), for example. FIG. 4A shows that one second island portion 21 corresponds to two rows of first island portions 11, but the disclosure is not limited thereto. In another embodiment, any one second island portion 21 disposed in the first non-display area NDA1 may correspond to n rows of first island portions 11 disposed in the display area DA (where n is a positive number of 3 or more).

The non-display area, e.g., the first non-display area NDA1, may include a first sub-non-display area SNDA1 in which the second island portions 21 and the second bridge portions 22 described above are disposed, and a second sub-non-display area SNDA2 between the first sub-non-display area SNDA1 and the display area DA. Third bridge portions 23 connecting the display area DA to the first sub-non-display area SNDA1 may be disposed in the second sub-non-display area SNDA2. One end portion of a third bridge portion 23 may be connected to the second island portion 21 and/or the second bridge portion 22, and an opposite end portion of the third bridge portion 23 may be connected to the first island portion 11 and/or the first bridge portion 12.

The third bridge portion 23 may have a serpentine shape. In an embodiment, the shape of the third bridge portion 23 may be different from the shape of each of the first bridge portion 12 and the second bridge portion 22. In an embodiment, as shown in FIG. 4A, the third bridge portion 23 may have an approximately omega (Ω) shape that is convex toward the second direction (e.g., the y direction or the -y direction). Neighboring (adjacent) third bridge portions 23 arranged in the second direction (e.g., the y direction or the -y direction) may have structures that are symmetrical to each other, for example one of the neighboring (adjacent) third bridge portions 23 arranged in the second direction (e.g., the y direction or the -y direction) may be convex in the y direction, and a remaining (the other) one may be convex in the -y direction). A structure in which third opening areas CS3 and fourth opening areas CS4, which have different shapes, are repeated may be provided between the third bridge portions 23. A width of the third bridge portion 23 may be different from a width of the first bridge portion 12 and a width of the second bridge portion 22. In an embodiment, the width of the third bridge portion 23 may be greater than the width of the first bridge portion 12 and may be less than the width of the second bridge portion 22.

FIG. 4A shows that the second island portion 21 and the second bridge portion 22 in the non-display area (e.g., the first non-display area NDA1) have different shapes from the first island portion 11 and the first bridge portion 12 in the display area DA, respectively. In another embodiment, the second island portion 21 and the second bridge portion 22 in the non-display area may have the same shapes as the first island portion 11 and the first bridge portion 12 in the display area DA, respectively.

FIG. 4B is an enlarged view of an embodiment of the region IV of FIG. 3, which is a portion of the display device 1.

Referring to FIG. 4B, the display device 1 may include, in the display area DA, the first island portions 11 spaced apart from each other and the first bridge portions 12 spaced apart from each other by the first opening area CS1 and connecting neighboring (adjacent) first island portions 11 to each other. The structure of the display area DA of FIG. 4B may be the same as the structure of the display area DA described above with reference to FIG. 4A.

The display device 1 may include the second island portions 21 and the second bridge portions 22, which are disposed in the non-display area, e.g., the first non-display area NDA1. In an embodiment, the second island portions 21 and the second bridge portions 22 may have substantially the same shapes as the first island portions 11 and the first bridge portions 12, respectively.

The second island portions 21 may be spaced apart from each other in the first direction (e.g., the x direction or the -x direction) and the second direction (e.g., the y direction or the -y direction) in the non-display area, e.g., the first non-display area NDA1. The second bridge portions 22 may be respectively connected to neighboring (adjacent) second island portions 21. The second bridge portions 22 may be spaced apart from each other by the second opening area CS2 disposed between the second bridge portions 22.

The second opening area CS2 may have substantially the same shape as that of the first opening area CS1. In an embodiment, a second opening area CS2 having an approximately H shape and a second opening area CS2 having an approximately I shape may be alternately and repeatedly arranged in the non-display area, e.g., the first non-display area NDA1, for example. Both end portions of each second bridge portion 22 are respectively connected to neighboring (adjacent) second island portions 21, but one side of each second bridge portion 22 may be spaced apart from one side of a neighboring (adjacent) second island portion 21 and/or one side of another second bridge portion 22 by the second opening area CS2.

Each second island portion 21 may be connected to four second bridge portions 22. Each second island portion 21 may include drivers of the gate driving circuit GDC (refer to FIG. 3) described above with reference to FIG. 3.

The second island portions 21 of any one row arranged in the first non-display area NDA1 may correspond to the first island portions 11 of any one row arranged in the display area DA. In an embodiment, the second island portions 21 arranged in an (i)-th row in the first direction (e.g., the x direction or the -x direction) in the first non-display area NDA1 may correspond to the first island portions 11 arranged in the same row in the display area DA, e.g., the (i)-th row (where i is a positive number greater than 0), for example.

The display device 1 may include the third bridge portions 23 disposed in the second sub-non-display area SNDA2 connecting the display area DA to the first sub-non-display area SNDA1. The non-display area, e.g., the first non-display area NDA1, may include the first sub-non-display area SNDA1 in which the second island portions 21 and the second bridge portions 22 are disposed, and the second sub-non-display area SNDA2 including the third bridge portions 23 and disposed between the first sub-non-display area SNDA1 and the display area DA. The third bridge portion 23 may be substantially the same as the first bridge portion 12 and the second bridge portion 22. In an embodiment, the width of the third bridge portion 23 may be equal to the width of the first bridge portion 12 and the width of the second bridge portion 22, for example.

FIG. 4C is an enlarged plan view of an embodiment of the region IV of FIG. 3, which is a portion of the display device 1.

Referring to FIG. 4C, the display device 1 may include, in the display area DA, the first island portions 11 spaced apart from each other in the first direction (e.g., the x direction or the -x direction) and the second direction (e.g., the y direction or the -y direction), and the first bridge portions 12 extending to neighboring (adjacent) first island portions 11.

The first bridge portions 12 may be spaced apart from each other by the first opening area CS1 defined between the first bridge portions 12. The first bridge portion 12 may have a serpentine shape. In an embodiment, as shown in FIG. 4C, the first bridge portion 12 may have an approximate shape of ‘the letter S,’ for example

Each first island portion 11 may be extended to a plurality of first bridge portions 12. In an embodiment, each first island portion 11 may be extended to four first bridge portions 12, for example. Two first bridge portions 12 may be respectively disposed on opposite sides of the first island portion 11 in the first direction (e.g., the x direction or the -x direction), and the remaining two bridge portions 12 may be respectively disposed on opposite sides of the first island portion 11 in the second direction (e.g., the y direction or the -y direction). The four first bridge portion 12 may be respectively extended to four sides of the first island portion 11. Each of the four first bridge portions 12 may be neighboring (adjacent) to each of corners of the first island portion 11.

The display device 1 may include, in the non-display area, e.g., the first non-display area NDA1 shown in FIG. 4C, the second island portions 21 spaced apart from each other in the first direction (e.g., the x direction or the -x direction) and the second direction (e.g., the y direction or the -y direction), and the second bridge portions 22 extending to neighboring (adjacent) second island portions 21.

The second bridge portions 22 may be spaced apart from each other by the second opening area CS2 disposed between the second bridge portions 22. The second bridge portion 22 may have a serpentine shape. In an embodiment, as shown in FIG. 4C, the second bridge portion 22 may have an approximate shape of ‘the letter S,’ for example The size and/or width of the second bridge portion 22 may be different from the size and/or width of the first bridge portion 12. In an embodiment, the size and/or width of the second bridge portion 22 may be greater than the size and/or width of the first bridge portion 12, for example. The radius of curvature of a rounded portion of the second bridge portion 22 may be different from the radius of curvature of a rounded portion of the first bridge portion 12. In an embodiment, the radius of curvature of the rounded portion of the second bridge portion 22 may be greater than the radius of curvature of the rounded portion of the first bridge portion 12, for example.

Each second island portion 21 may be extended to a plurality of second bridge portions 22. Each second island portion 21 may be extended to four second bridge portions 22. Two second bridge portions 22 may be respectively disposed on opposite sides of the second island portion 21 in the first direction (e.g., the x direction or the -x direction), and the remaining two second bridge portions 22 may be respectively disposed on opposite sides of the second island portion 21 in the second direction (e.g., the y direction or the -y direction). In an embodiment, the four second bridge portions 22 may be respectively extended to four sides of the second island portion 21. Each second bridge portion 22 may be extended to a central portion of each side of the second island portion 21.

The second island portions 21 of any one row disposed in the first non-display area NDA1 may correspond to the first island portions 11 of a plurality of rows arranged in the display area DA. In an embodiment, the second island portions 21 of any one row disposed in the first non-display area NDA1 may correspond to the first island portions 11 arranged in the (i)-th row and the first island portions 11 arranged in the (i+1)-th row in the display area DA (where i is a positive number greater than 0), for example. In another embodiment, the second island portions 21 of any one row may correspond to n rows of the first island portions 11 (where n is a positive number of 3 or more).

The non-display area, e.g., the first non-display area NDA1, may include the first sub-non-display area SNDA1 in which the second island portions 21 and the second bridge portions 22 described above are disposed, and the second sub-non-display area SNDA2 between the first sub-non-display area SNDA1 and the display area DA. The third bridge portions 23 extending to the display area DA and the first sub-non-display area SNDA1 may be disposed in the second sub-non-display area SNDA2. One end portion of the third bridge portion 23 may be extended to the second island portion 21, and an opposite end portion of the third bridge portion 23 may be extended to the first island portion 11. In an embodiment, one end portion of the third bridge portion 23 may be extended to the central portion of one side of the second island portion 21, and an opposite end portion of the third bridge portion 23 may be extended to the central portion of one side of the first island portion 11.

The third bridge portion 23 may have a serpentine shape. In an embodiment, the shape of the third bridge portion 23 may be different from the shape of each of the first bridge portion 12 and the second bridge portion 22. A width of the third bridge portion 23 may be different from a width of the first bridge portion 12 and a width of the second bridge portion 22. The width of the third bridge portion 23 may be greater than the width of the first bridge portion 12 and may be less than the width of the second bridge portion 22. The third opening areas CS3 and the fourth opening areas CS4, which have different shapes, may be alternately arranged between the third bridge portions 23 in the second direction (e.g., the y direction or the -y direction).

FIG. 5 is a schematic cross-sectional view of an embodiment of the first island portion 11 and the first bridge portion 12, which are disposed in the display area DA of the display device 1.

Referring to FIG. 5, the first island portion 11 and the first bridge portion 12, which are disposed in the display area DA, may be spaced apart from each other with the first opening area CS1 therebetween. The first island portion 11 may include light-emitting elements LED and a circuit electrically connected to the light-emitting elements LED and configured to drive the light-emitting elements LED, e.g., a pixel driving circuit part PC, and the first bridge portion 12 may include a line WL electrically connected to pixel driving circuit parts PC respectively disposed in neighboring (adjacent) first island portions 11.

When looking at the first island portion 11, a buffer layer 111 including an inorganic insulating material may be disposed on a substrate 100, and the pixel driving circuit part PC may be disposed on the buffer layer 111. An insulating layer IL including an inorganic insulating material and/or an organic insulating material may be disposed between the pixel driving circuit part PC and the light-emitting element LED. The light-emitting element LED may be disposed on the insulating layer IL and may be electrically connected to a corresponding pixel driving circuit part PC. The light-emitting elements LED may emit light of different colors or the same color. In an embodiment, the light-emitting elements LED may respectively emit red, green, and blue light. In some embodiments, the light-emitting elements LED may emit white light. In another embodiment, the light-emitting elements LED may respectively emit red, green, blue, and white light.

The substrate 100 may include a polymer resin, such as polyethersulfone, polyarylate, polyetherimide, polyethylene naphthalate, polyethylene terephthalate, polyphenylene sulfide, polyimide, polycarbonate, cellulose triacetate, and cellulose acetate propionate. In an embodiment, the substrate 100 may be a single layer including the polymer resin described above. In another embodiment, the substrate 100 may have a multi-layered structure including a base layer including the polymer resin described above, and a barrier layer including an inorganic insulating material. The substrate 100 including the polymer resin may be flexible, rollable, or bendable.

In an embodiment, FIG. 5 shows three pixel driving circuit parts PC disposed in each first island portion 11 and three light-emitting elements LED are connected to each of the pixel driving circuit parts PC, but the disclosure is not limited thereto. In another embodiment, the number of each of the pixel driving circuit parts PC and the light-emitting elements LED, which are disposed in the first island portion 11, may be one, two, or four or more.

An encapsulation layer 300 may be disposed on the light-emitting element LED and may protect the light-emitting element LED from external force and/or moisture penetration. The encapsulation layer 300 may include an inorganic encapsulation layer and/or an organic encapsulation layer. In some embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin. In some embodiments, the encapsulation layer 300 may include urethane epoxy acrylate. The encapsulation layer 300 may include a photosensitive material, e.g., a material such as photoresist.

When looking at the first bridge portion 12, the insulating layer IL including an organic insulating material may be disposed on the substrate 100. When the display device 1 is stretched, the first bridge portion 12, which is relatively transformed, may not include a layer including an inorganic insulating material that is prone to cracks, unlike the first island portion 11.

In an embodiment, the substrate 100 corresponding to the first bridge portion 12 may have the same stacked structure as the substrate 100 corresponding to the first island portion 11. In an embodiment, the substrate 100 corresponding to the first bridge portion 12 and the substrate 100 corresponding to the first island portion 11 may be polymer resin layers formed together in the same process. In another embodiment, the substrate 100 corresponding to the first bridge portion 12 may have a stacked structure different from that of the substrate 100 corresponding to the first island portion 11. In some embodiments, the substrate 100 corresponding to the first island portion 11 may have a multi-layered structure including a base layer including a polymer resin and a barrier layer including an inorganic insulating material, and the substrate 100 corresponding to the first bridge portion 12 may have a structure of a polymer resin layer without a layer including an inorganic insulating material.

As described above, lines WL of the first bridge portion 12 may be signal lines (e.g., gate lines, data lines, or the like) for providing electrical signals to transistors included in the pixel driving circuit part PC of the first island portion 11, or may be voltage lines (e.g., driving voltage lines, initialization voltage lines, or the like) for providing voltages. The encapsulation layer 300 may also be disposed in the first bridge portion 12. In another embodiment, the encapsulation layer 300 may not be in the first bridge portion 12.

Referring to FIGS. 4A to 4C, and 5, the substrate 100 corresponding to the first island portion 11 and the substrate 100 corresponding to the first bridge portion 12 may be connected to each other. In other words, the plan views previously shown in FIGS. 4A to 4C may be substantially the same as the plan view of the substrate 100 of FIG. 5. That is, the substrate 100 may include an area corresponding to the first island portion 11 and an area corresponding to the first bridge portion 12, and an opening 100OP1 having the same shape as that of the first opening area CS1 may be defined in the substrate 100.

Similarly, the encapsulation layer 300 corresponding to the first island portion 11 and the encapsulation layer 300 corresponding to the first bridge portion 12 may be connected to each other. In an embodiment, the plan views previously shown in FIGS. 4A to 4C may be substantially the same as the plan view of the encapsulation layer 300, for example. In other words, the encapsulation layer 300 may include an area corresponding to the first island portion 11 and an area corresponding to the first bridge portion 12, and an opening 300OP1 having the same shape as that of the first opening area CS1 may be defined in the encapsulation layer 300.

A circuit-light-emitting element layer 200 between the substrate 100 and the encapsulation layer 300 may include the buffer layer 111, the pixel driving circuit part PC, the line WL, the insulating layer IL, and the light-emitting element LED. Similar to the substrate 100, the plan views previously shown in FIGS. 4A to 4C may be substantially the same as the plan view of the circuit-light-emitting element layer 200. In other words, the circuit-light-emitting element layer 200 may define an opening 200OP1 having the same shape as that of the first opening area CS1.

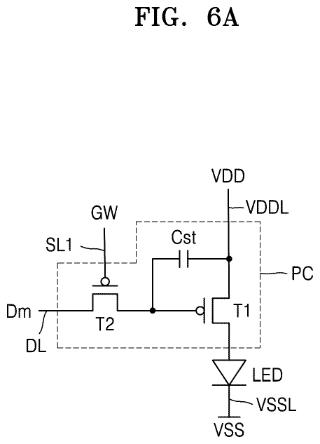

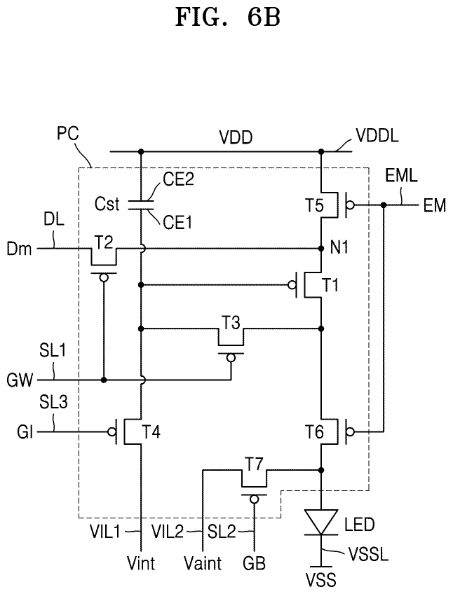

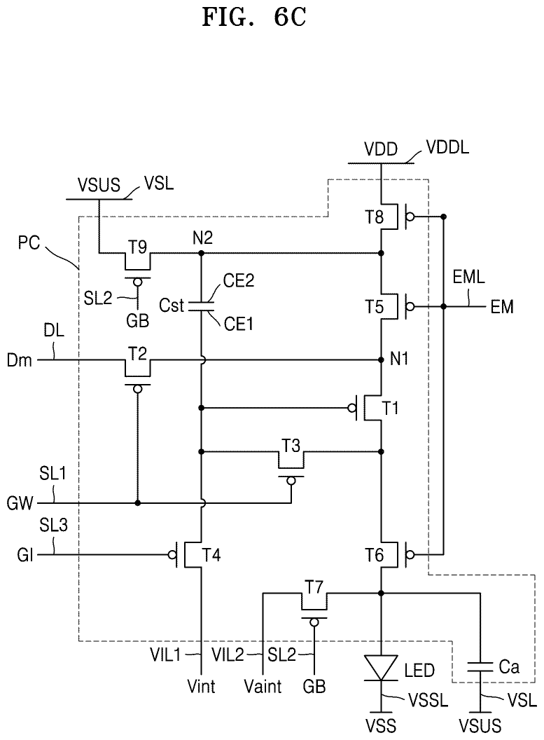

FIGS. 6A to 6C are equivalent circuit diagrams each illustrating an embodiment of a sub-pixel of the display device 1 (refer to FIG. 5).

Referring to FIG. 6A, the light-emitting element LED corresponding to the sub-pixel may be electrically connected to the pixel driving circuit part PC, and the pixel driving circuit part PC may include a first transistor T1, a second transistor T2, and a storage capacitor Cst. The pixel driving circuit part PC may be electrically connected to signal lines and voltage lines. The signal lines may include a gate line, such as a first scan line SL1, and a data line DL, and the voltage lines may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may transmit, to the first transistor T1, a data signal Dm input from the data line DL according to the first scan signal GW input from the first scan line SL1.

The storage capacitor Cst may be electrically connected to the second transistor T2 and the first voltage line VDDL, and may store a voltage corresponding to the difference between a voltage received from the second transistor T2 and a first power voltage VDD supplied by the first voltage line VDDL.

The first transistor T1 is a driving transistor, which may control a driving current flowing through the light-emitting element LED. The first transistor T1 may be connected to the first voltage line VDDL and the storage capacitor Cst. The first transistor T1 may control the driving current flowing through the light-emitting element LED from the first voltage line VDDL in accordance to a voltage value stored in the storage capacitor Cst. The light-emitting element LED may emit light having a predetermined brightness according to the driving current. A first electrode of the light-emitting element LED may be electrically connected to the first transistor T1, and a second electrode thereof may be electrically connected to a second voltage line VSSL providing a second power voltage VSS.

Although FIG. 6A illustrates that the pixel driving circuit part PC includes two transistors and one storage capacitor, in another embodiment, the pixel driving circuit part PC may include three or more transistors.

Referring to FIG. 6B, the pixel driving circuit part PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit part PC is electrically connected to signal lines and voltage lines. The signal lines may include gate lines, such as the first scan line SL1, a second scan line SL2, a third scan line SL3, and an emission control line EML, and the data line DL. The voltage lines may include first and second initialization voltage lines VIL1 and VIL2, and the first voltage line VDDL.

The first voltage line VDDL may transmit the first power voltage VDD to the first transistor T1. The first initialization voltage line VIL1 may transmit, to the pixel driving circuit part PC, a first initialization voltage Vint initializing the first transistor T1. The second initialization voltage line VIL2 may transmit, to the pixel driving circuit part PC, a second initialization voltage Vaint initializing the first electrode of the light-emitting element LED.

The first transistor T1 may be electrically connected to the first voltage line VDDL via the fifth transistor T5 and may be electrically connected to the light-emitting element LED via the sixth transistor T6. The first transistor T1 serves as a driving transistor and receives the data signal Dm in response to a switching operation of the second transistor T2 to supply a driving current to the light-emitting element LED.

The second transistor T2 is a data write transistor, which is electrically connected to the first scan line SL1 and the data line DL. The second transistor T2 is electrically connected to the first voltage line VDDL via the fifth transistor T5. The second transistor T2 is turned on in response to the first scan signal GW received through the first scan line SL1 and performs a switching operation of providing the data signal Dm provided with the data line DL to a first node N1.

The third transistor T3 is electrically connected to the first scan line SL1 and is electrically connected to the light-emitting element LED via the sixth transistor T6. The third transistor T3 may be turned on in response to the first scan signal GW received through the first scan line SL1 to diode-connect the first transistor T1.

The fourth transistor T4 is a first initialization transistor, which is electrically connected to the third scan line SL3 and the first initialization voltage line VIL1. The fourth transistor T4 is turned on in response to a third scan signal GI received through the third scan line SL3 to provide the first initialization voltage Vint from the first initialization voltage line VIL1 to a gate electrode of the first transistor T1 to initialize a voltage of the gate electrode of the first transistor T1. The third scan signal GI may correspond to a first scan signal of another pixel driving circuit disposed in a previous row of the corresponding pixel driving circuit part PC.

The fifth transistor T5 may be an operation control transistor, and the sixth transistor T6 may be an emission control transistor. The fifth transistor T5 and the sixth transistor T6 are electrically connected to the emission control line EML and are simultaneously turned on in response to an emission control signal EM received through the emission control line EML to form a current path so that a driving current may flow in a direction from the first voltage line VDDL to the light-emitting element LED.

The seventh transistor T7 is a second initialization transistor, which may be electrically connected to the second scan line SL2, the second initialization voltage line VIL2, and the sixth transistor T6. The seventh transistor T7 may be turned on in response to a second scan signal GB received through the second scan line SL2 to provide the second initialization voltage Vaint from the second initialization voltage line VIL2 to the first electrode of the light-emitting element LED to initialize the first electrode of the light-emitting element LED.

The storage capacitor Cst may include the first electrode CE1 and the second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to the difference between voltages of opposite ends of the first voltage line VDDL and the gate electrode of the first transistor T1.

Referring to FIG. 6C, the pixel driving circuit part PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit part PC is electrically connected to signal lines and voltage lines. The signal lines may include gate lines, such as the first scan line SL1, the second scan line SL2, the third scan line SL3, and the emission control line EML, and the data line DL. The voltage lines may include the first and second initialization voltage lines VIL1 and VIL2, a maintenance voltage line VSL, and the first voltage line VDDL.

The first voltage line VDDL may transmit the first power voltage VDD to the first transistor T1. The first initialization voltage line VIL1 may transmit, to the pixel driving circuit part PC, the first initialization voltage Vint initializing the first transistor T1. The second initialization voltage line VIL2 may transmit, to the pixel driving circuit part PC, the second initialization voltage Vaint initializing the first electrode of the light-emitting element LED. The maintenance voltage line VSL may provide a maintenance voltage VSUS to a second node N2, e.g., the second electrode CE2 of the storage capacitor Cst, during an initialization section and a data write section.

The first transistor T1 may be electrically connected to the first voltage line VDDL via the fifth transistor T5 and the eighth transistor T8, and may be electrically connected to the light-emitting element LED via the sixth transistor T6. The first transistor T1 may serve as a driving transistor and receive the data signal Dm in response to a switching operation of the second transistor T2 to supply a driving current to the light-emitting element LED.

The second transistor T2 is electrically connected to the first scan line SL1 and the data line DL, and is electrically connected to the first voltage line VDDL via the fifth transistor T5 and the eighth transistor T8. The second transistor T2 is turned on in response to the first scan signal GW received through the first scan line SL1 and performs a switching operation of transmitting the data signal Dm transmitted through the data line DL to the first node N1.

The third transistor T3 is electrically connected to the first scan line SL1 and is electrically connected to the light-emitting element LED via the sixth transistor T6. The third transistor T3 may be turned on in response to the first scan signal GW received through the first scan line SL1 to diode-connect the first transistor T1, thereby compensating for a threshold voltage of the first transistor T1.

The fourth transistor T4 is electrically connected to the third scan line SL3 and the first initialization voltage line VIL1 and turned on in response to the third scan signal GI received through the third scan line SL3 to provide the first initialization voltage Vint from the first initialization voltage line VIL1 to the gate electrode of the first transistor T1 to initialize a voltage of the gate electrode of the first transistor T1. The third scan signal GI may correspond to a first scan signal of another pixel driving circuit disposed in a previous row of the corresponding pixel driving circuit part PC.

The fifth transistor T5, the sixth transistor T6, and the eighth transistor T8 are electrically connected to the emission control line EML and simultaneously turned on in response to the emission control signal EM received through the emission control line EML to form a current path so that the driving current may flow in a direction from the first voltage line VDDL to the light-emitting element LED.

The seventh transistor T7 is a second initialization transistor, which may be electrically connected to the second scan line SL2, the second initialization voltage line VIL2, and the sixth transistor T6. The seventh transistor T7 is turned on in response to the second scan signal GB received through the second scan line SL2 to provide the second initialization voltage Vaint from the second initialization voltage line VIL2 to the first electrode of the light-emitting element LED to initialize the first electrode of the light-emitting element LED.

The ninth transistor T9 may be electrically connected to the second scan line SL2, the second electrode CE2 of the storage capacitor Cst, and the maintenance voltage line VSL. The ninth transistor T9 may be turned on in response to the second scan signal GB received through the second scan line SL2 to provide the maintenance voltage VSUS to the second node N2, e.g., the second electrode CE2 of the storage capacitor Cst, during an initialization section and a data write section.

Each of the eighth transistor T8 and the ninth transistor T9 may be electrically connected to the second node N2, e.g., the second electrode CE2 of the storage capacitor Cst. In some embodiments, the eighth transistor T8 may be turned off and the ninth transistor T9 may be turned on during the initialization section and the data write section, and the eighth transistor T8 may be turned on and the ninth transistor T9 may be turned off during an emission section. Because the maintenance voltage VSUS is transmitted to the second node N2 during the initialization section and the data write section, the brightness uniformity (e.g., long-range uniformity (“LRU”)) of a display device according to a voltage drop of the first voltage line VDDL may be improved.

The storage capacitor Cst may include the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the maintenance voltage line VSL, and the first electrode of the light-emitting element LED. The auxiliary capacitor Ca may store and maintain a voltage corresponding to a voltage difference between the first electrode of the light-emitting element LED and the maintenance voltage line VSL while the seventh transistor T7 and the ninth transistor T9 are turned on, so that a problem in which black brightness increases when the sixth transistor T6 is turned off may be prevented.

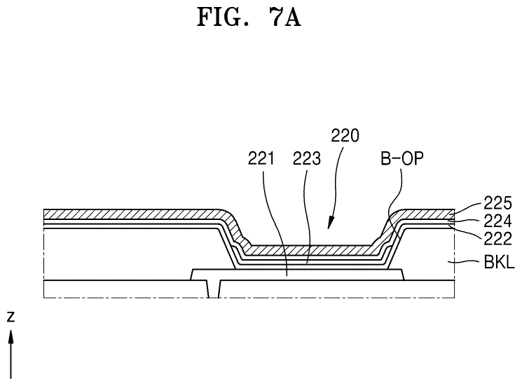

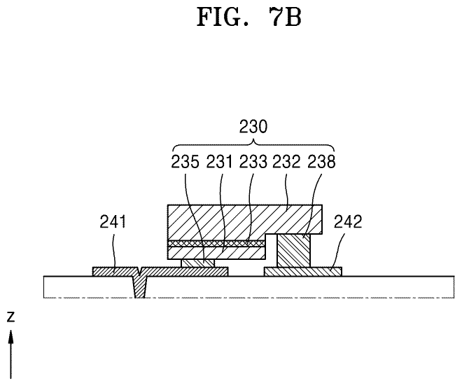

FIG. 7A is a schematic cross-sectional view of an embodiment of a light-emitting element of the display device 1.

Referring to FIG. 7A, the light-emitting element in an embodiment may include an organic light-emitting diode 220 including an organic material. The organic light-emitting diode 220 may include a first electrode 221 disposed on an insulating layer, a second electrode 225 facing the first electrode 221, and an emission layer 223 arranged between the first electrode 221 and the second electrode 225. A first functional layer 222 may be disposed between the first electrode 221 and the emission layer 223, and a second functional layer 224 may be disposed between the emission layer 223 and the second electrode 225.

An edge of the first electrode 221 may be covered with a bank layer BKL including an insulating material. The bank layer BKL may define an opening B-OP overlapping a central portion of the first electrode 221.

The first electrode 221 may include a conductive oxide, such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any combinations thereof. In another embodiment, the first electrode 221 may further include a layer including ITO, IZO, ZnO, or In₂O₃ above/below the reflective layer stated above.

The emission layer 223 may include a polymer organic material or a low-molecular-weight organic material, which emits light of a predetermined color. The first functional layer 222 may include a hole transport layer (“HTL”) and/or a hole injection layer (“HIL”). The second functional layer 224 may include an electron transport layer (“ETL”) and/or an electron injection layer (“EIL”).

The second electrode 225 may include a conductive material having a relatively low work function. In an embodiment, the second electrode 225 may include a (semi)transparent layer including Ag, Mg, Al, Pt, Pd, Au, Ni, Nd, Ir, Cr, lithium (Li), calcium (Ca), alloys thereof, or the like, for example. In an alternative embodiment, the second electrode 225 may further include a layer, such as ITO, IZO, ZnO, or In₂O₃, above the (semi)transparent layer including the above-stated material.

FIG. 7B is a schematic cross-sectional view of an embodiment of a light-emitting element of the display device 1.

Referring to FIG. 7B, the light-emitting element in an embodiment may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may respectively be electrically connected to a first electrode pad 241 and a second electrode pad 242, which are disposed in the same layer.

In some embodiments, the first semiconductor layer 231 may include a p-type semiconductor layer. The p-type semiconductor layer is a semiconductor material with a composition formula of InxAlyGa1-x-yN (0≤x≤1, 0≤y≤1, 0≤x+y≤1), which may, e.g., be selected from among GaN, AlN, AlGaN, InGaN, InN, InAlGaN, AlInN, or the like, and may be doped with a p-type dopant such as Mg, Zn, Ca, Sr, Ba, or the like.

The second semiconductor layer 232 may include, e.g., an n-type semiconductor layer. The n-type semiconductor layer is a semiconductor material having a composition formula of InxAlyGa1-x-yN (0≤x≤1, 0≤y≤1, 0≤x+y≤1), which may, e.g., be selected from among GaN, AlN, AlGaN, InGaN, InN, InAlGaN, AlInN, or the like, and may be doped with an n-type dopant such as Si, Ge, Sn, or the like.

The intermediate layer 233 is a region where electrons and holes are recombined. As the electrons and holes are recombined, the intermediate layer 233 may transition to a relatively low energy level and generate light having a corresponding wavelength. In an embodiment, the intermediate layer 233 may be formed by including a semiconductor material having a composition formula of InxAlyGa1-x-yN (0≤x≤1, 0≤y≤1, 0≤x+y≤1), and may be formed as a single-quantum well structure or a multi-quantum well (“MQW”) structure, for example. In addition, the intermediate layer 233 may also include a quantum wire structure or a quantum dot structure.

FIG. 7B shows that the first semiconductor layer 231 includes a p-type semiconductor layer, and the second semiconductor layer 232 includes an n-type semiconductor layer, but the disclosure is not limited thereto. In another embodiment, the first semiconductor layer 231 may include an n-type semiconductor layer, and the second semiconductor layer 232 may include a p-type semiconductor layer.

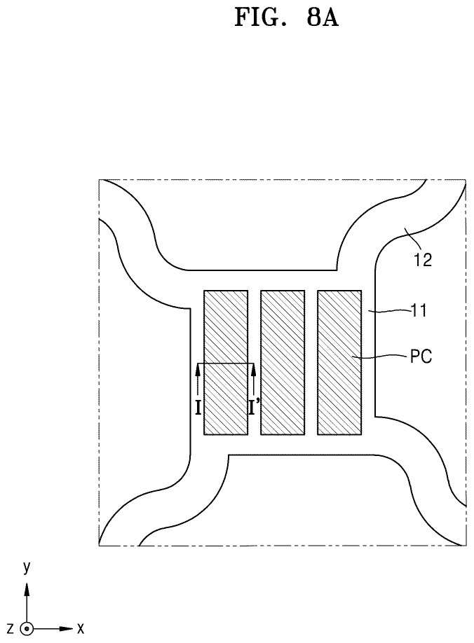

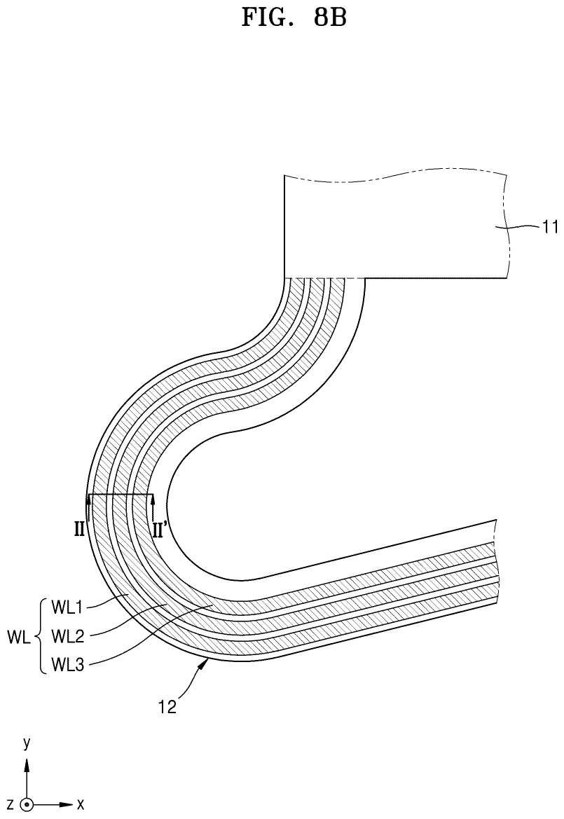

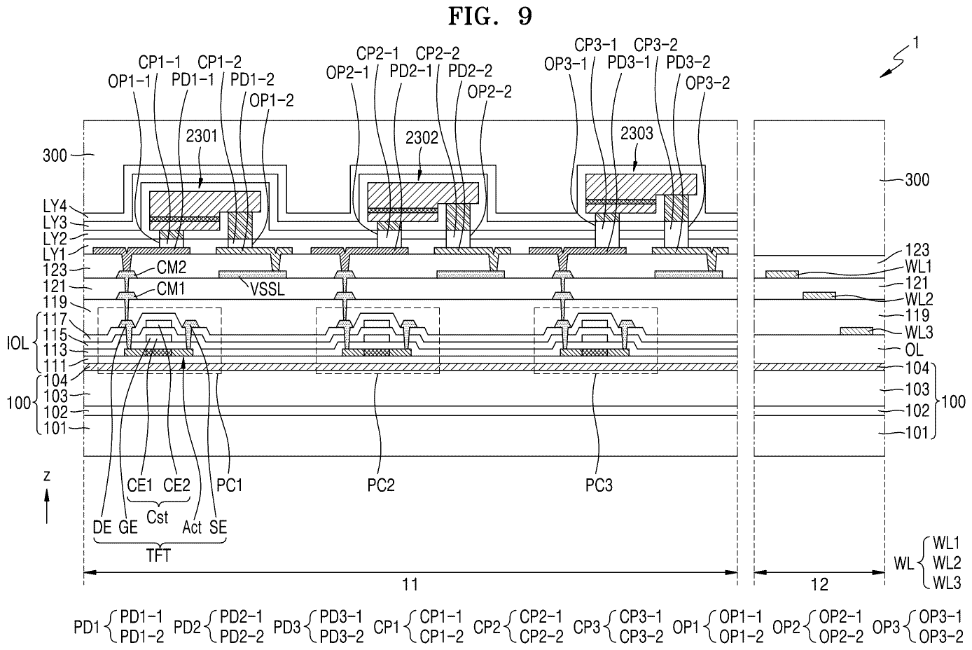

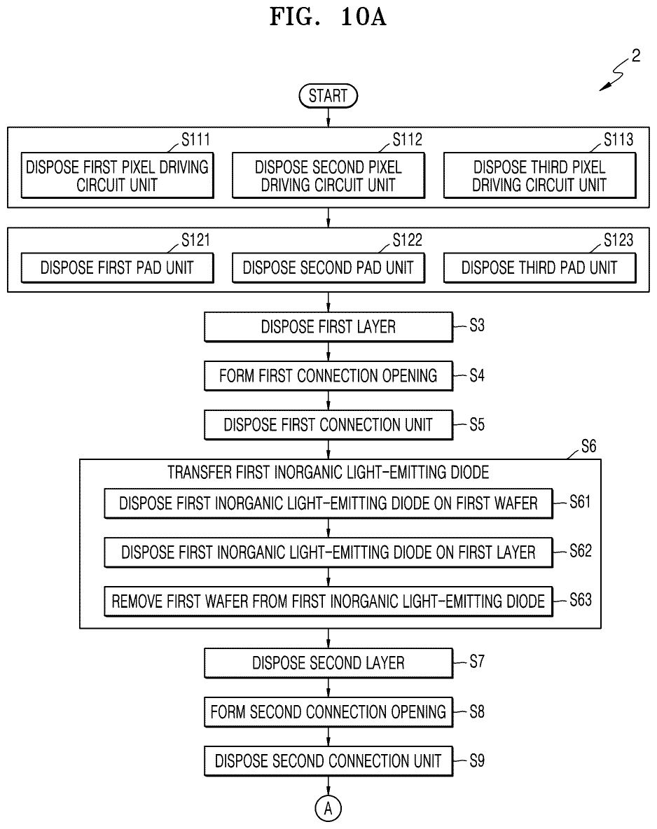

FIG. 8A is an enlarged plan view of an embodiment of the first island portion 11 of the display device 1 in an embodiment, and FIG. 8B is a plan view schematically illustrating an embodiment of the arrangement of lines on the first bridge portion 12 of the display device 1. In addition, FIG. 9 shows schematic cross-sectional views of the display device 1, taken along line I-I′ of FIG. 8A and a line II-II′ of FIG. 8B, respectively.

Referring to FIG. 8A, the first island portion 11 disposed in the display area DA may include light-emitting elements and the pixel driving circuit part PC electrically connected to the light-emitting elements. The pixel driving circuit part PC may include transistors and at least one capacitor, as described above. FIG. 8A shows that three pixel driving circuit parts PC are disposed in the first island portion 11, but the disclosure is not limited thereto. In another embodiment, the number of each of the pixel driving circuit parts PC and the light-emitting elements, which are disposed in the first island portion 11, may be one, two, or four or more. Hereinafter, a case of three pixel driving circuit parts PC is described.

Referring to FIG. 9, the substrate 100 corresponding to the first island portion 11 may include a first base layer 101, a first barrier layer 102, a second base layer 103, and a second barrier layer 104. Each of the first base layer 101 and the second base layer 103 may include a polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like. Each of the first barrier layer 102 and the second barrier layer 104 may include an inorganic insulating material, such as silicon oxide, silicon nitride, and silicon oxynitride.

A first pixel driving circuit part PC1, a second pixel driving circuit part PC2, and a third pixel driving circuit part PC3 may be disposed on the substrate 100. The first pixel driving circuit part PC1, the second pixel driving circuit part PC2, and the third pixel driving circuit part PC3 may correspond to the three pixel driving circuit parts PC (refer to FIG. 8A) described above with reference to FIG. 8A. The first pixel driving circuit part PC1, the second pixel driving circuit part PC2, and the third pixel driving circuit part PC3 may be spaced apart from each other.

A buffer layer 111 may be disposed on the substrate 100, and each of the first pixel driving circuit part PC1, the second pixel driving circuit part PC2, and the third pixel driving circuit part PC3 may be disposed on the buffer layer 111. The buffer layer 111 may include an inorganic insulating material, such as silicon oxide, silicon nitride, and silicon oxynitride.

Each of the first pixel driving circuit part PC1, the second pixel driving circuit part PC2, and the third pixel driving circuit part PC3 may include a thin-film transistor TFT and a storage capacitor Cst.

The thin-film transistor TFT may include a semiconductor layer Act, a gate electrode GE, a source electrode SE, and a drain electrode DE. FIG. 9 shows a top-gate type in which the gate electrode GE is disposed on the semiconductor layer Act with a gate insulating layer 113 therebetween, but in another embodiment, the thin-film transistor TFT may be a bottom-gate type.

The semiconductor layer Act may include polysilicon. In an alternative embodiment, the semiconductor layer Act may include amorphous silicon, an oxide semiconductor, an organic semiconductor, or the like. The gate electrode GE may include a low-resistance metal material. The gate electrode GE may include a conductive material including molybdenum (Mo), Al, copper (Cu), titanium (Ti), or the like, and may include a multi-layer or a single layer, each including the material stated above.

The gate insulating layer 113 between the semiconductor layer Act and the gate electrode GE may include an inorganic insulating material, such as silicon oxide, silicon nitride, silicon oxynitride, aluminum oxide, and titanium oxide. The gate insulating layer 113 may include a single layer or a multi-layer, each including the material described above.

The source electrode SE and the drain electrode DE may be disposed in the same layer, e.g., on a second inter-insulating layer 117, and may include the same material as each other. Each of the source electrode SE and the drain electrode DE may include a conductive material and may include a multi-layer or a single layer. The second inter-insulating layer 117 may include an inorganic insulating material, such as silicon oxide, silicon nitride, silicon oxynitride, aluminum oxide, and titanium oxide, and may be a single layer or a multi-layer, each including the material described above.

The storage capacitor Cst may include the first electrode CE1 and the second electrode CE2, which overlap each other with a first inter-insulating layer 115 therebetween. The storage capacitor Cst may overlap the thin-film transistor TFT. In this regard, FIG. 9 shows that the gate electrode GE of the thin-film transistor TFT is the first electrode CE1 of the storage capacitor Cst. In another embodiment, the storage capacitor Cst may not overlap the thin-film transistor TFT. The storage capacitor Cst may be covered by the second inter-insulating layer 117. The second electrode CE2 of the storage capacitor Cst may include a conductive material and may include a multi-layer or a single layer. The first inter-insulating layer 115 may be disposed between the gate insulating layer 113 and the second inter-insulating layer 117. The first inter-insulating layer 115 may include an inorganic insulating material, such as silicon oxide, silicon nitride, silicon oxynitride, aluminum oxide, and titanium oxide, and may be a single layer or a multi-layer, each including the material described above.

An inorganic insulating material layer IOL on the substrate 100 may include, e.g., the buffer layer 111, the gate insulating layer 113, the first inter-insulating layer 115, and the second inter-insulating layer 117.

A first organic insulating layer 119 may be disposed on the second inter-insulating layer 117, and a second organic insulating layer 121 may be disposed on the first organic insulating layer 119. Each of the first organic insulating layer 119 and the second organic insulating layer 121 may include an organic insulating material, such as polyimide.

The second voltage line VSSL may be disposed on the second organic insulating layer 121, and a third organic insulating layer 123 may be disposed on the second organic insulating layer 121 and the second voltage line VSSL. The third organic insulating layer 123 may include an organic insulating material, such as polyimide. The second voltage line VSSL may include a conductive material, and may include a multi-layer or a single layer.

A first pad part PD1 may be disposed on the first pixel driving circuit part PC1 to be electrically connected to the first pixel driving circuit part PC1. The first pad part PD1 may be disposed on the third organic insulating layer 123. The first pad part PD1 may include a first-1 pad PD1-1 and a first-2 pad PD1-2, which are spaced apart from each other. The first-1 pad PD1-1 may be electrically connected to the thin-film transistor TFT through a first connection electrode CM1 between the first organic insulating layer 119 and the second organic insulating layer 121 and a second connection electrode CM2 between the second organic insulating layer 121 and the third organic insulating layer 123. In addition, the first-2 pad PD1-2 may be electrically connected to the second voltage line VSSL.

A second pad part PD2 may be disposed on the second pixel driving circuit part PC2 to be electrically connected to the second pixel driving circuit part PC2. The second pad part PD2 may be spaced apart from the first pad part PD1. The second pad part PD2 may be disposed on the third organic insulating layer 123. The second pad part PD2 may include a second-1 pad PD2-1 and a second-2 pad PD2-2, which are spaced apart from each other. The second-1 pad PD2-1 may be electrically connected to the thin-film transistor TFT, similarly to the first-1 pad PD1-1. In addition, the second-2 pad PD2-2 may be electrically connected to the second voltage line VSSL.

A third pad part PD3 may be disposed on the third pixel driving circuit part PC3 to be electrically connected to the third pixel driving circuit part PC3. The third pad part PD3 may be spaced apart from the first pad part PD1 and the second pad part PD2. The third pad part PD3 may be disposed on the third organic insulating layer 123. The third pad part PD3 may include a third-1 pad PD3-1 and a third-2 pad PD3-2, which are spaced apart from each other. The third-1 pad PD3-1 may be electrically connected to the thin-film transistor TFT, similarly to the first-1 pad PD1-1. In addition, the third-2 pad PD3-2 may be electrically connected to the second voltage line VSSL.

A first layer LY1 may be disposed on the third organic insulating layer 123. The first layer LY1 may be disposed on the first pad part PD1, the second pad part PD2, and the third pad part PD3 to cover each of the first pad part PD1, the second pad part PD2, and the third pad part PD3.

A first inorganic light-emitting diode 2301 electrically connected to the first pad part PD1 may be disposed above the first layer LY1. The first inorganic light-emitting diode 2301 is described with reference to FIG. 7B. A first connection opening OP1 defined between the first inorganic light-emitting diode 2301 and the first pad part PD1 may be formed in the first layer LY1. A first connection part CP1 may be accommodated in the first connection opening OP1, which penetrates the first layer LY1, to electrically connect the first pad part PD1 to the first inorganic light-emitting diode 2301. The first connection part CP1 may include a conductive material.

The first connection opening OP1 may include a first-1 connection opening OP1-1 and a first-2 connection opening OP1-2. In addition, the first connection part CP1 may include a first-1 connection part CP1-1 accommodated in the first-1 connection opening OP1-1 and a first-2 connection part CP1-2 accommodated in the first-2 connection opening OP1-2. The first-1 connection part CP1-1 may electrically connect the first-1 pad PD1-1 to the first electrode 235 (refer to FIG. 7B) of the first inorganic light-emitting diode 2301. In addition, the first-2 connection part CP1-2 may electrically connect the first-2 pad PD1-2 to the second electrode 238 (refer to FIG. 7B) of the first inorganic light-emitting diode 2301.

A second layer LY2 may be disposed on the first layer LY1 and the first inorganic light-emitting diode 2301. The second layer LY2 may cover the first inorganic light-emitting diode 2301. The second layer LY2 may surround upper and side surfaces of the first inorganic light-emitting diode 2301.

A second inorganic light-emitting diode 2302 electrically connected to the second pad part PD2 may be disposed on the second layer LY2. The second inorganic light-emitting diode 2302 is described with reference to FIG. 7B. A second connection opening OP2 defined between the second inorganic light-emitting diode 2302 and the second pad part PD2 may be formed in the first layer LY1 and the second layer LY2. A second connection part CP2 may be accommodated in the second connection opening OP2, which penetrates each of the first layer LY1 and the second layer LY2, to electrically connect the second pad part PD2 to the second inorganic light-emitting diode 2302. The second connection part CP2 may include a conductive material.

The second connection opening OP2 may include a second-1 connection opening OP2-1 and a second-2 connection opening OP2-2. In addition, the second connection part CP2 may include a second-1 connection part CP2-1 accommodated in the second-1 connection opening OP2-1 and a second-2 connection part CP2-2 accommodated in the second-2 connection opening OP2-2. The second-1 connection part CP2-1 may electrically connect the second-1 pad PD2-1 to the first electrode 235 (refer to FIG. 7B) of the second inorganic light-emitting diode 2302. In addition, the second-2 connection part CP2-2 may electrically connect the second-2 pad PD2-2 to the second electrode 238 (refer to FIG. 7B) of the second inorganic light-emitting diode 2302.

A third layer LY3 may be disposed on the second layer LY2 and the second inorganic light-emitting diode 2302. The third layer LY3 may cover the second inorganic light-emitting diode 2302. The third layer LY3 may surround upper and side surfaces of the second inorganic light-emitting diode 2302.

A third inorganic light-emitting diode 2303 electrically connected to the third pad part PD3 may be disposed on the third layer LY3. The third inorganic light-emitting diode 2303 is described with reference to FIG. 7B. A third connection opening OP3 defined between the third inorganic light-emitting diode 2303 and the third pad part PD3 may be formed in the first layer LY1, the second layer LY2, and the third layer LY3. A third connection part CP3 may be accommodated in the third connection opening OP3, which penetrates each of the first layer LY1, the second layer LY2, and the third layer LY3, to electrically connect the third pad part PD3 to the third inorganic light-emitting diode 2303. The third connection part CP3 may include a conductive material.

The third connection opening OP3 may include a third-1 connection opening OP3-1 and a third-2 connection opening OP3-2. In addition, the third connection part CP3 may include a third-1 connection part CP3-1 accommodated in the third-1 connection opening OP3-1 and a third-2 connection part CP3-2 accommodated in the third-2 connection opening OP3-2. The third-1 connection part CP3-1 may electrically connect the third-1 pad PD3-1 to the first electrode 235 (refer to FIG. 7B) of the third inorganic light-emitting diode 2303. In addition, the third-2 connection part CP3-2 may electrically connect the third-2 pad PD3-2 to the second electrode 238 (refer to FIG. 7B) of the third inorganic light-emitting diode 2303.

A fourth layer LY4 may be disposed on the third layer LY3 and the third inorganic light-emitting diode 2303. The fourth layer LY4 may cover the third inorganic light-emitting diode 2303. The fourth layer LY4 may surround upper and side surfaces of the third inorganic light-emitting diode 2303.

In such a structure, the first inorganic light-emitting diode 2301 may be disposed on the first layer LY1, the second inorganic light-emitting diode 2302 may be disposed on the first layer LY1 and the second layer LY2, and the third inorganic light-emitting diode 2303 may be disposed on the first layer LY1, the second layer LY2, and the third layer LY3. Accordingly, a height of the second inorganic light-emitting diode 2302 from the substrate 100 may be greater than a height of the first inorganic light-emitting diode 2301 from the substrate 100. In addition, a height of the third inorganic light-emitting diode 2303 from the substrate 100 may be greater than the height of the second inorganic light-emitting diode 2302 from the substrate 100.

The first inorganic light-emitting diode 2301, the second inorganic light-emitting diode 2302, and the third inorganic light-emitting diode 2303 may emit light of different colors. In an embodiment, the first inorganic light-emitting diode 2301 may emit red light, the second inorganic light-emitting diode 2302 may emit green light, and the third inorganic light-emitting diode 2303 may emit blue light, for example. However, this is an illustrative embodiment, and the color of light emitted by each of the first inorganic light-emitting diode 2301, the second inorganic light-emitting diode 2302, and the third inorganic light-emitting diode 2303 is not limited thereto.

Each of the first layer LY1, the second layer LY2, the third layer LY3, and the fourth layer LY4 may include an insulating material. Each of the first layer LY1, the second layer LY2, the third layer LY3, and the fourth layer LY4 may include an inorganic material. In an embodiment, each of the first layer LY1, the second layer LY2, the third layer LY3, and the fourth layer LY4 may include a single film or a multi-layered film, each including silicon nitride (SiNₓ) and silicon oxide (SiOₓ), for example. However, this is an illustrative embodiment, and a material of each of the first layer LY1, the second layer LY2, the third layer LY3, and the fourth layer LY4 is not limited thereto. In an embodiment, each of the first layer LY1, the second layer LY2, the third layer LY3, and the fourth layer LY4 may also include an organic material, for example.

The first connection part CP1, the second connection part CP2, and the third connection part CP3 may include the same material as each other. In an embodiment, each of the first connection part CP1, the second connection part CP2, and the third connection part CP3 may include Ag, Mg, Al, Pt, Pd, Au, Ni, Nd, Ir, Cr, or any combinations thereof, for example. However, this is an illustrative embodiment, and a material of each of the first connection part CP1, the second connection part CP2, and the third connection part CP3 is not limited thereto.

An encapsulation layer 300 may be disposed on the fourth layer LY4. The first inorganic light-emitting diode 2301, the second inorganic light-emitting diode 2302, and the third inorganic light-emitting diode 2303 may be protected by the encapsulation layer 300, and the encapsulation layer 300 may include an inorganic encapsulation layer and/or an organic encapsulation layer or may include an organic material such as a resin.

In such a structure, the second layer LY2, the third layer LY3, and the fourth layer LY4 may surround the first inorganic light-emitting diode 2301. The third layer LY3 and the fourth layer LY4 may surround the second inorganic light-emitting diode 2302. The fourth layer LY4 may surround the third inorganic light-emitting diode 2303. Accordingly, the first inorganic light-emitting diode 2301, the second inorganic light-emitting diode 2302, and the third inorganic light-emitting diode 2303 may be protected from external impact or moisture penetration by at least one of the second layer LY2, the third layer LY3, and the fourth layer LY4.

Referring to FIG. 8B, the first bridge portion 12 may include a plurality of lines WL electrically connected to the pixel driving circuit parts PC disposed in next (adjacent) first island portions 11, respectively. As described above, the lines WL may be signal lines (e.g., gate lines, data lines, or the like) for providing electrical signals to transistors included in the pixel driving circuit part PC of the first island portion 11, or may be voltage lines (e.g., driving voltage lines, initialization voltage lines, or the like) for providing voltages. FIG. 8B shows that the plurality of lines WL, e.g., first to third lines WL1, WL2, and WL3, are disposed on the first bridge portion 12, but the disclosure is not limited thereto. In another embodiment, one line WL may also be disposed on the first bridge portion 12.

Referring to FIG. 9, in an embodiment, the substrate 100 corresponding to the first bridge portion 12 may have the same stacked structure as the substrate 100 corresponding to the first island portion 11. In an embodiment, the substrate 100 corresponding to the first bridge portion 12 may include the first base layer 101, the first barrier layer 102, the second base layer 103, and the second barrier layer 104. In another embodiment, the substrate 100 corresponding to the first bridge portion 12 may have a stacked structure different from that of the substrate 100 corresponding to the first island portion 11. The substrate 100 corresponding to the first bridge portion 12 may have a structure of the first base layer 101 and the second base layer 103.

The inorganic insulating material layer IOL may not be disposed on the substrate 100, and an insulating layer OL, the first organic insulating layer 119, and the second organic insulating layer 121 may be disposed on the substrate 100. The insulating layer OL may include an organic insulating material, such as polyimide. In an embodiment, the insulating layer OL may have a thickness corresponding to the inorganic insulating material layer IOL. In some embodiments, the insulating layer OL may also be omitted.

The plurality of lines WL, e.g., the first to third lines WL1, WL2, and WL3, may be disposed in different layers but may be electrically connected to the pixel driving circuit part PC. In an embodiment, the first line WL1 may be disposed between the second organic insulating layer 121 and the third organic insulating layer 123, the second line WL2 may be disposed between the first organic insulating layer 119 and the second organic insulating layer 121, and the third line WL3 may be disposed between the insulating layer OL and the first organic insulating layer 119, for example. However, the disclosure is not limited thereto, and in another embodiment, at least some of the first to third lines WL1, WL2, and WL3 may be disposed in the same layer.

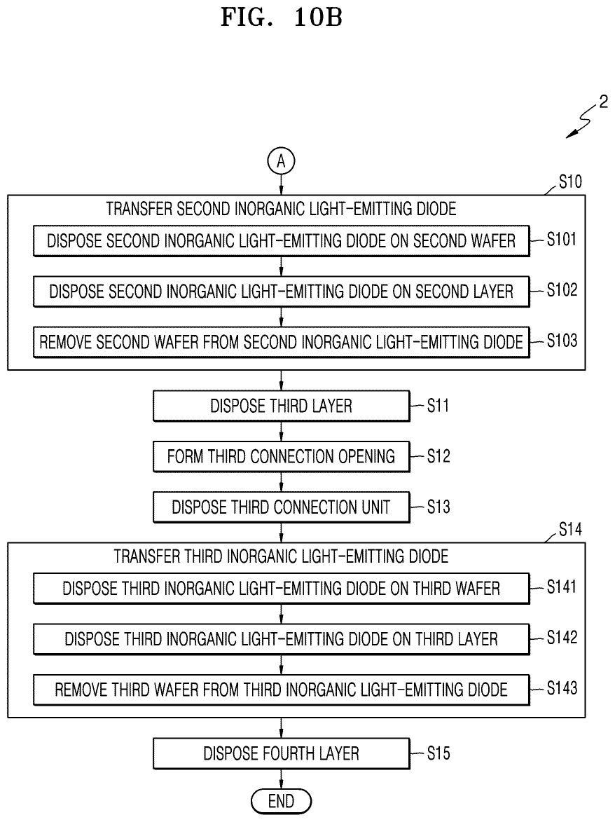

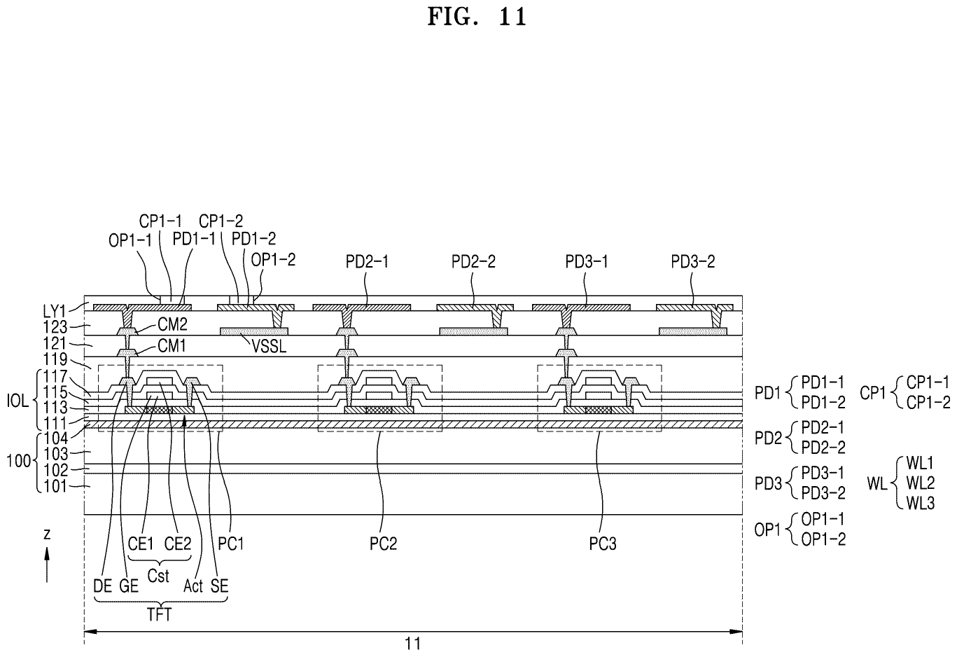

FIGS. 10A and 10B are schematic flowcharts each illustrating an embodiment of a method 2 of manufacturing a display device in an embodiment, and FIGS. 11 to 17 are schematic cross-sectional views of an embodiment of the display device 1.

Referring to FIGS. 10A to 17, the method 2 of manufacturing a display device is described.

In FIGS. 10A to 17, the same reference numerals as those in FIG. 9 refer to the same members, and redundant descriptions thereof are omitted.

Referring to FIGS. 10A, 10B, and 11, the method 2 of manufacturing a display device may include operation S111 of disposing the first pixel driving circuit part PC1 on the substrate 100, operation S112 of disposing the second pixel driving circuit part PC2 on the substrate 100, and operation S113 of disposing the third pixel driving circuit part PC3 on the substrate 100. Operation S111 of disposing the first pixel driving circuit part PC1, operation S112 of disposing the second pixel driving circuit part PC2, and operation S113 of disposing the third pixel driving circuit part PC3 may be simultaneously performed.

In addition, the method 2 of manufacturing a display device may include operation S121 of disposing the first pad part PD1 on the first pixel driving circuit part PC1 to be electrically connected to the first pixel driving circuit part PC1, operation S122 of disposing the second pad part PD2 on the second pixel driving circuit part PC2 to be electrically connected to the second pixel driving circuit part PC2, and operation S123 of disposing the third pad part PD3 on the third pixel driving circuit part PC3 to be electrically connected to the third pixel driving circuit part PC3. Operation S121 of disposing the first pad part PD1, operation S122 of disposing the second pad part PD2, and operation S123 of disposing the third pad part PD3 may be simultaneously performed.

The method 2 of manufacturing a display device may include operation S3 of disposing the first layer LY1 on the first pad part PD1, the second pad part PD2, and the third pad part PD3. The first layer LY1 may cover each of the first pad part PD1, the second pad part PD2, and the third pad part PD3.

The method 2 of manufacturing a display device may include operation S4 of forming the first connection opening OP1 in the first layer LY1 and operation S5 of disposing the first connection part CP1 in the first connection opening OP1. In operation S4 of forming the first connection opening OP1 in the first layer LY1, the first connection opening OP1 may expose the first pad part PD1 from the first layer LY1. In operation S5 of disposing the first connection part CP1 in the first connection opening OP1, the first connection part CP1 may contact the first pad part PD1.

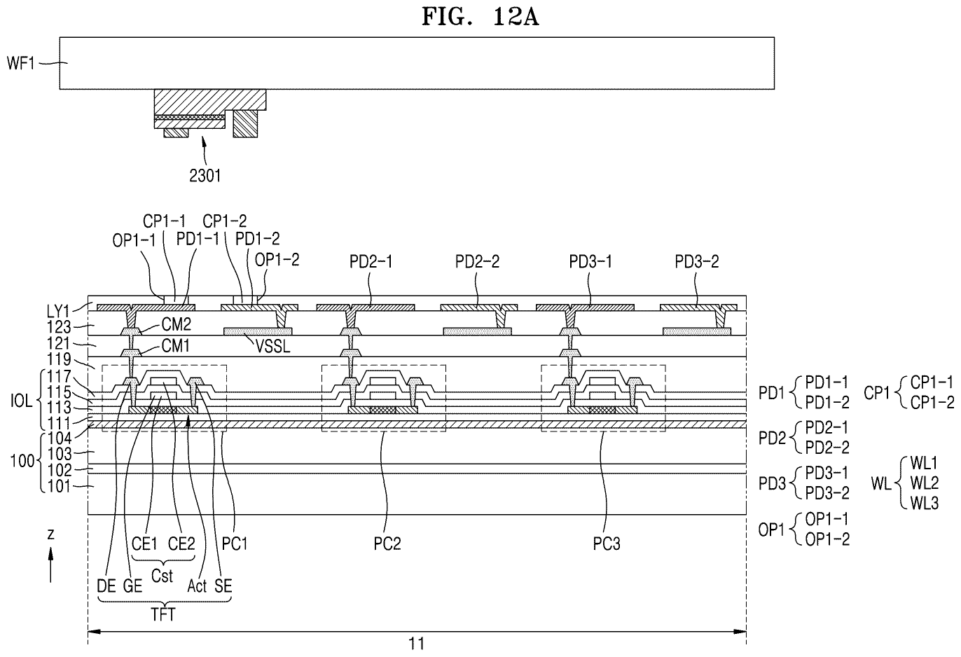

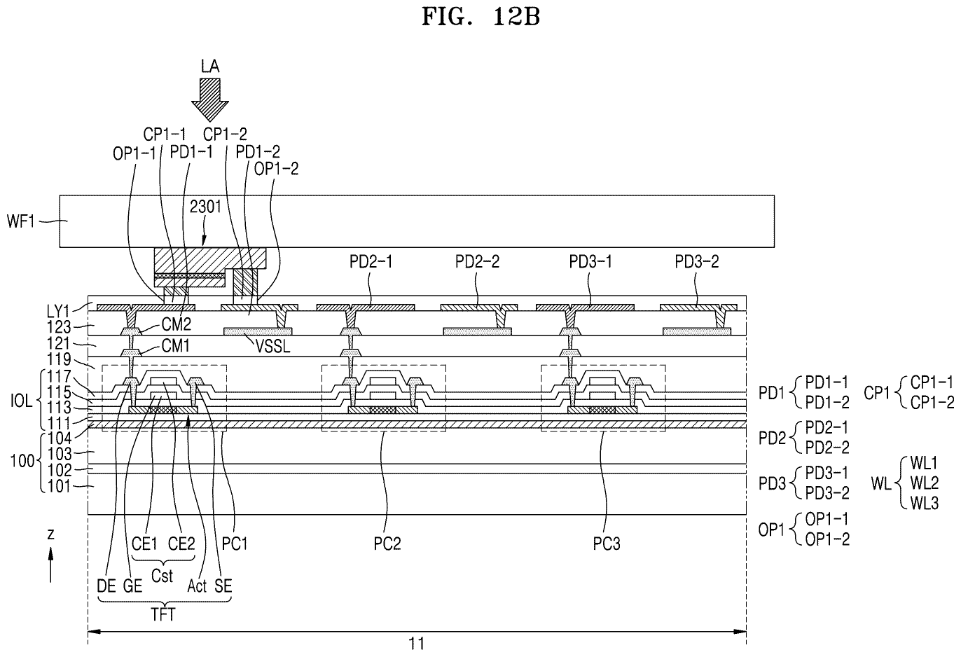

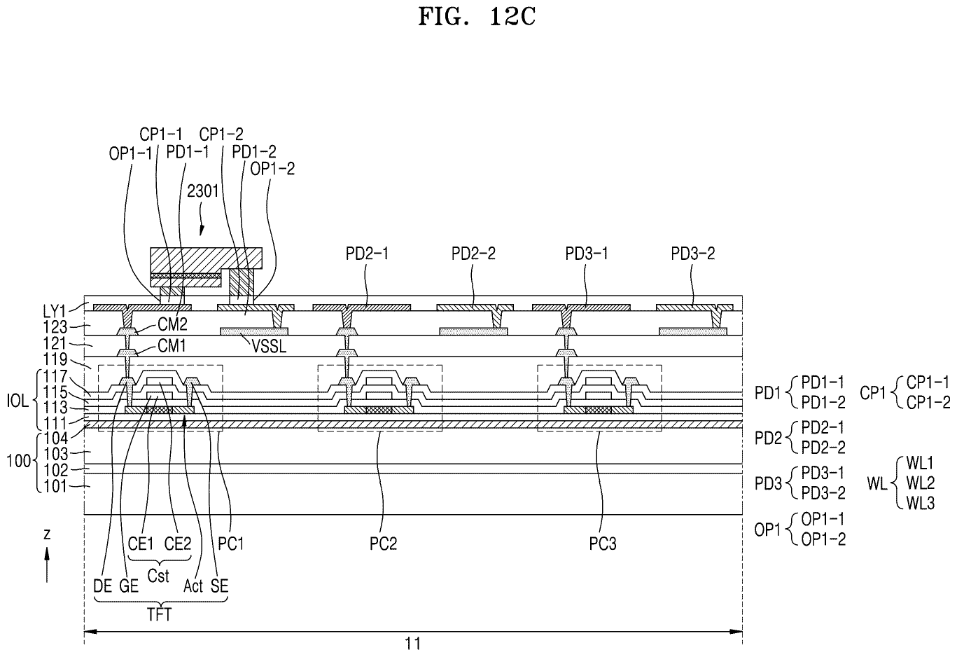

Referring to FIGS. 10A, 10B, and 12A to 12C, the method 2 of manufacturing a display device may include operation S6 of transferring the first inorganic light-emitting diode 2301 onto the first pad part PD1.

Referring to FIGS. 10A, 10B, and 12A, operation S6 of transferring the first inorganic light-emitting diode 2301 may include operation S61 of disposing the first inorganic light-emitting diode 2301 on a first wafer WF1.

The first inorganic light-emitting diode 2301 may be formed by forming a material, such as gallium nitride (GaN) or indium gallium nitride (InGaN), on the first wafer WF1 to grow a crystal layer, cutting the crystal layer into individual chips, and forming an electrode. In an embodiment, the first wafer WF1 may include sapphire, silicon carbide (SiC), gallium nitride (GaN), zinc oxide (ZnO), or the like, for example, but is not limited thereto.

FIG. 12A shows an operation in which one first inorganic light-emitting diode 2301 corresponding to one first island portion 11 is formed on the first wafer WF1, but a plurality of first inorganic light-emitting diodes 2301 emitting light of the same color may be formed on the first wafer WF1 to correspond to a plurality of first island portions 11 (refer to FIGS. 4A to 4C).

Referring to FIGS. 10A, 10B, and 12B, operation S6 of transferring the first inorganic light-emitting diode 2301 may include operation S62 of disposing the first inorganic light-emitting diode 2301 on the first layer LY1 so that the first inorganic light-emitting diode 2301 is electrically connected to the first pad part PD1. The first connection part CP1 may electrically connect the first pad part PD1 to the first inorganic light-emitting diode 2301.

Referring to FIGS. 10A, 10B, and 12C, operation S6 of transferring the first inorganic light-emitting diode 2301 may include operation S63 of removing the first wafer WF1 from the first inorganic light-emitting diode 2301.

A temporary layer (not shown) may be formed between the first wafer WF1 and the first inorganic light-emitting diode 2301. A laser beam LA having a relatively high energy wavelength may be irradiated to the first wafer WF1 by a laser lift off (“LLO”) process. At this time, the first inorganic light-emitting diode 2301 may be separated from the first wafer WF1 due to rapid melting and vaporization of the surface of the temporary layer (not shown).

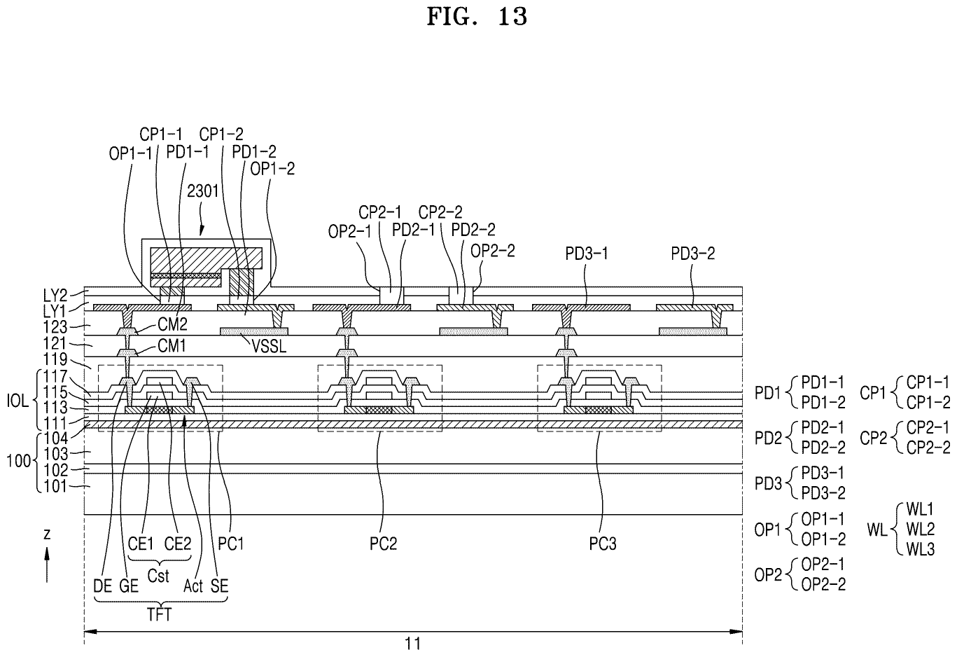

Referring to FIGS. 10A, 10B, and 13, the method 2 of manufacturing a display device may include operation S7 of disposing the second layer LY2 on the first layer LY1. The second layer LY2 may cover the first inorganic light-emitting diode 2301.

The method 2 of manufacturing a display device may include operation S8 of forming the second connection opening OP2 in the first layer LY1 and the second layer LY2, and operation S9 of disposing the second connection part CP2 in the second connection opening OP2. In operation S8 of forming the second connection opening OP2 in the first layer LY1 and the second layer LY2, the second connection opening OP2 may expose the second pad part PD2 from the first layer LY1 and the second layer LY2. In operation S9 of disposing the second connection part CP2 in the second connection opening OP2, the second connection part CP2 may contact the second pad part PD2.

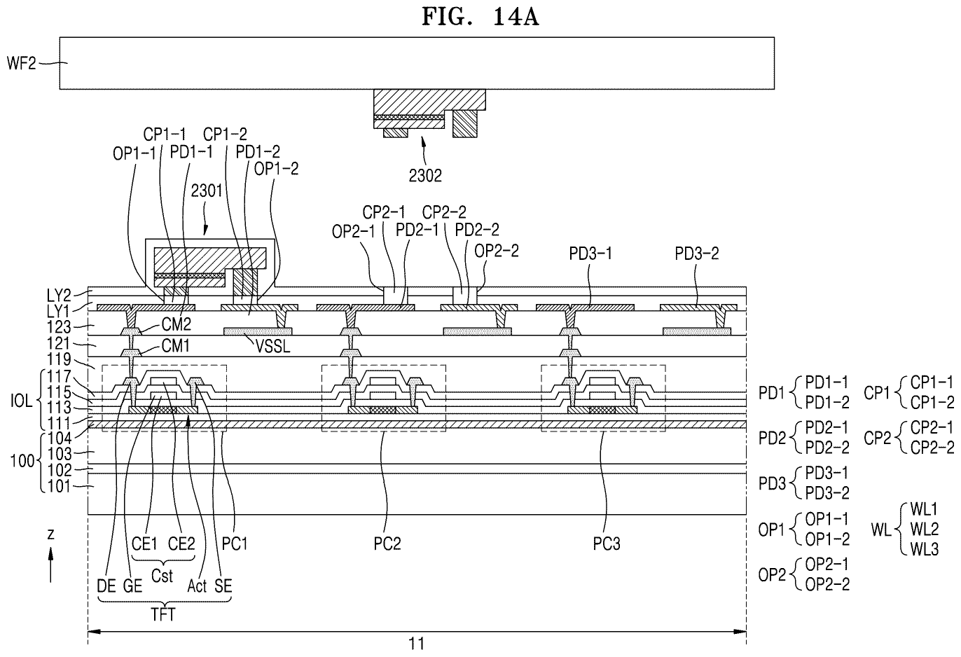

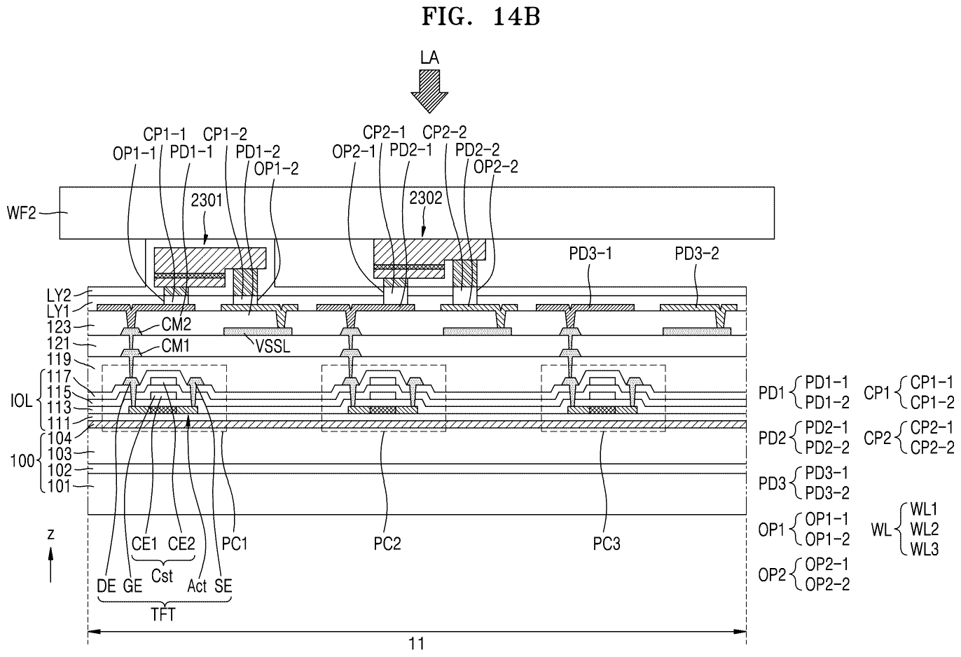

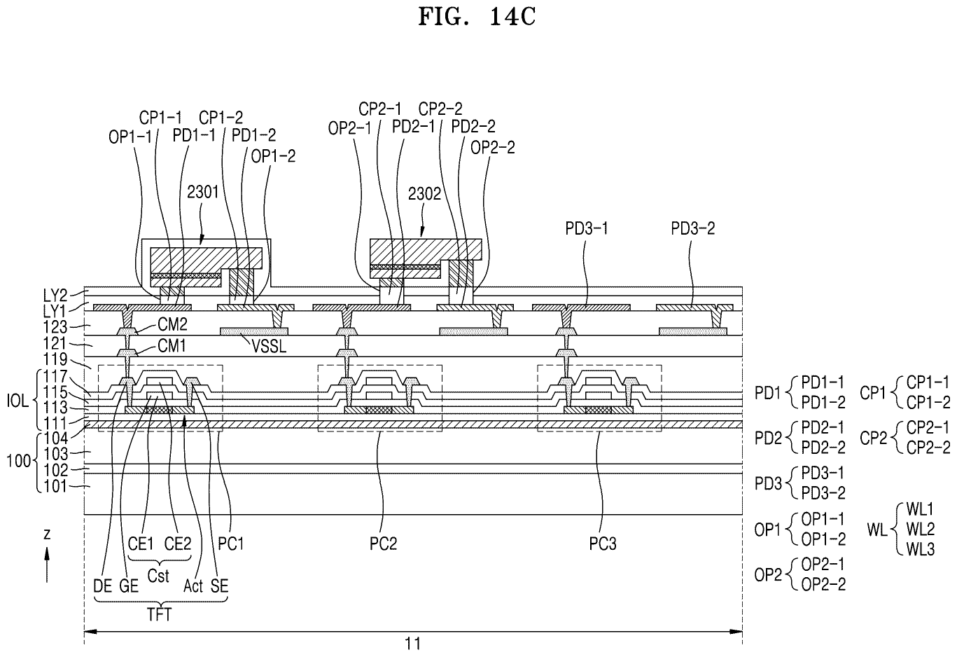

Referring to FIGS. 10A, 10B, and 14A to 14C, the method 2 of manufacturing a display device may include S10 of transferring the second inorganic light-emitting diode 2302 onto the second pad part PD2.

Referring to FIGS. 10A, 10B, and 14A, operation S10 of transferring the second inorganic light-emitting diode 2302 may include operation S101 of disposing the second inorganic light-emitting diode 2302 on a second wafer WF2.

The second inorganic light-emitting diode 2302 may be formed by forming a material, such as gallium nitride (GaN) or indium gallium nitride (InGaN), on the second wafer WF2 to grow a crystal layer, cutting the crystal layer into individual chips, and forming an electrode. In an embodiment, the second wafer WF2 may include sapphire, silicon carbide (SiC), gallium nitride (GaN), zinc oxide (ZnO), or the like, for example, but is not limited thereto.

FIG. 14A shows an operation in which one second inorganic light-emitting diode 2302 corresponding to one first island portion 11 is formed on the second wafer WF2, but a plurality of second inorganic light-emitting diodes 2302 emitting light of the same color may be formed on the second wafer WF2 to correspond to the plurality of first island portions 11 (refer to FIGS. 4A to 4C).

Referring to FIGS. 10A, 10B, and 14B, operation S10 of transferring the second inorganic light-emitting diode 2302 may include operation S102 of disposing the second inorganic light-emitting diode 2302 on the second layer LY2 so that the second inorganic light-emitting diode 2302 is electrically connected to the second pad part PD2. The first connection part CP1 may electrically connect the second pad part PD2 to the second inorganic light-emitting diode 2302.

Referring to FIGS. 10A, 10B, and 14C, operation S10 of transferring the second inorganic light-emitting diode 2302 may include operation S103 of removing the second wafer WF2 from the second inorganic light-emitting diode 2302.

A temporary layer (not shown) may be formed between the second wafer WF2 and the second inorganic light-emitting diode 2302. The laser beam LA having a relatively high energy wavelength may be irradiated to the second wafer WF2 by an LLO process. At this time, the second inorganic light-emitting diode 2302 may be separated from the second wafer WF2 due to rapid melting and vaporization of the surface of the temporary layer (not shown).

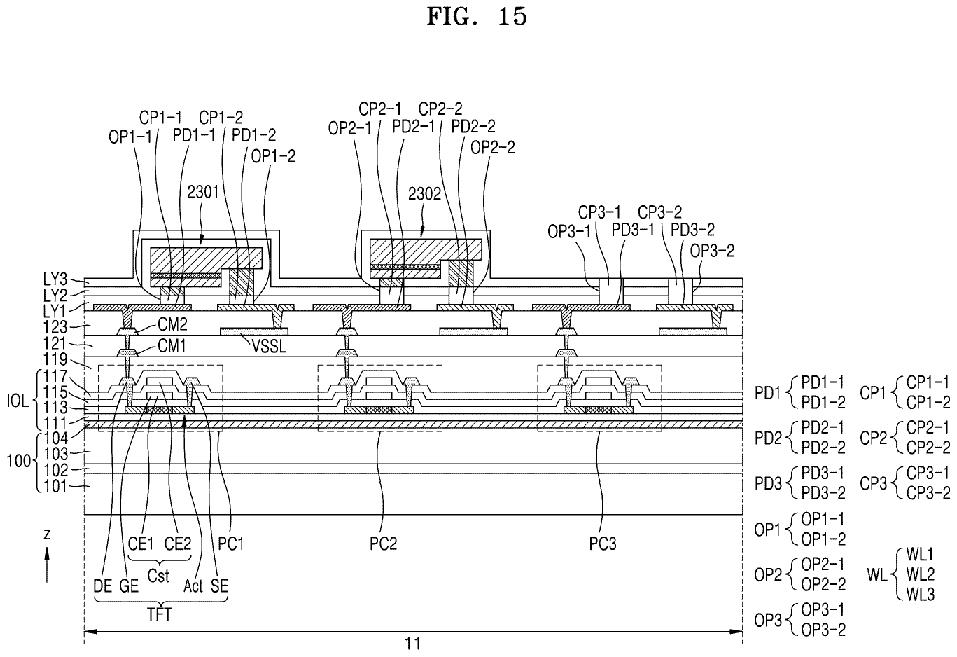

Referring to FIGS. 10A, 10B, and 15, the method 2 of manufacturing a display device may include operation S11 of disposing the third layer LY3 on the second layer LY2. The third layer LY3 may cover the second inorganic light-emitting diode 2302.

The method 2 of manufacturing a display device may include operation S12 of forming the third connection opening OP3 in the first layer LY1, the second layer LY2, and the third layer LY3, and operation S13 of disposing the third connection part CP3 in the third connection opening OP3. In operation S12 of forming the third connection opening OP3 in the first layer LY1, the second layer LY2, and the third layer LY3, the third connection opening OP3 may expose the third pad part PD3 from the first layer LY1, the second layer LY2, and the third layer LY3. In operation S13 of disposing the third connection part CP3 in the third connection opening OP3, the third connection part CP3 may contact the third pad part PD3.

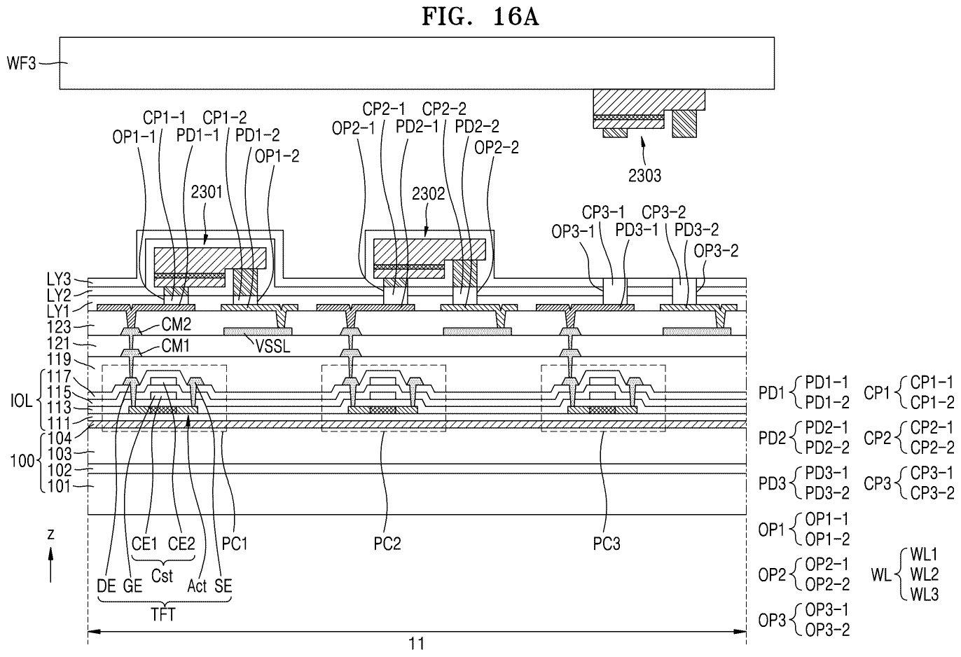

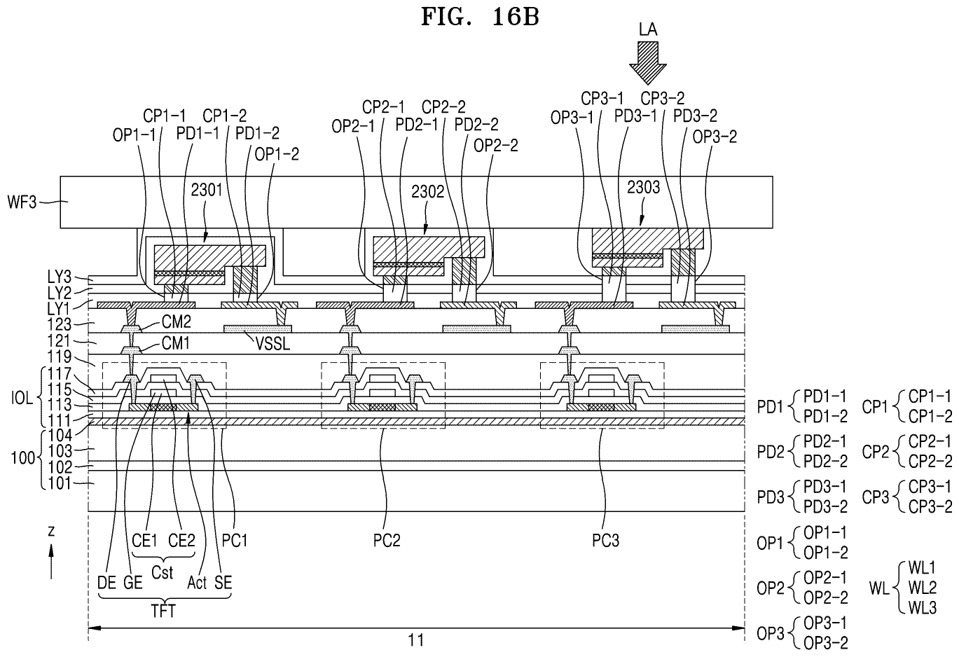

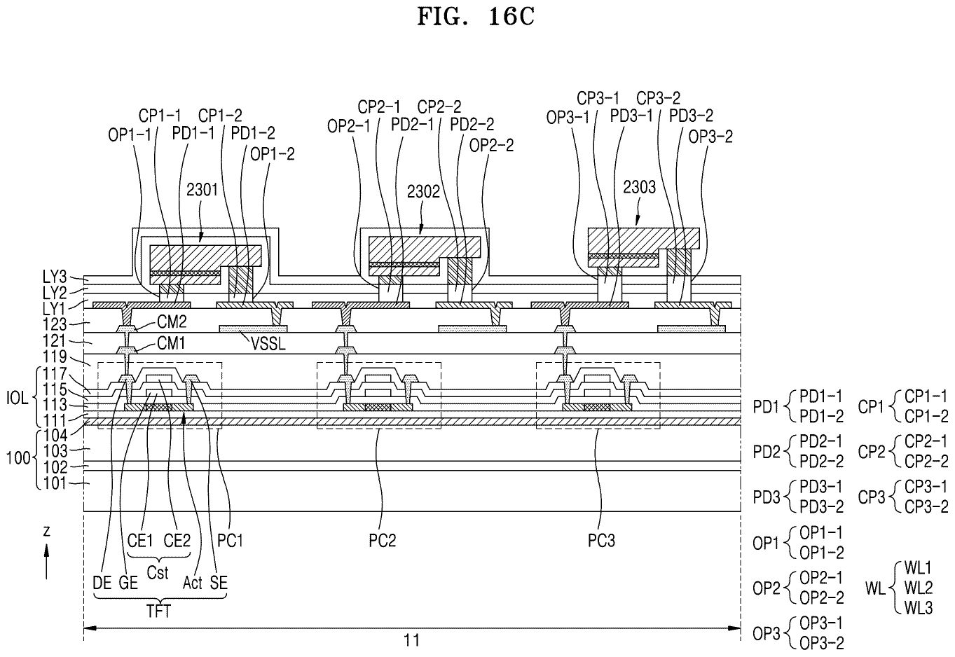

Referring to FIGS. 10A, 10B, and 16A to 16C, the method 2 of manufacturing a display device may include operation S14 of transferring the third inorganic light-emitting diode 2303 onto the third pad part PD3.

Referring to FIGS. 10A, 10B, and 16A, operation S14 of transferring the third inorganic light-emitting diode 2303 may include operation S141 of disposing the third inorganic light-emitting diode 2303 on a third wafer WF3.

The third inorganic light-emitting diode 2303 may be formed by forming a material, such as gallium nitride (GaN) or indium gallium nitride (InGaN), on the third wafer WF3 to grow a crystal layer, cutting the crystal layer into individual chips, and forming an electrode. In an embodiment, the third wafer WF3 may include sapphire, silicon carbide (SiC), gallium nitride (GaN), zinc oxide (ZnO), or the like, for example, but is not limited thereto.

FIG. 16A shows an operation in which one third inorganic light-emitting diode 2303 corresponding to one first island portion 11 is formed on the third wafer WF3, but a plurality of third inorganic light-emitting diodes 2303 emitting light of the same color may be formed on the third wafer WF3 to correspond to the plurality of first island portions 11 (refer to FIGS. 4A to 4C).

Referring to FIGS. 10A, 10B, and 16B, operation S14 of transferring the third inorganic light-emitting diode 2303 may include operation S142 of disposing the third inorganic light-emitting diode 2303 on the third layer LY3 so that the third inorganic light-emitting diode 2303 is electrically connected to the third pad part PD3. The third connection part CP3 may electrically connect the third pad part PD3 to the third inorganic light-emitting diode 2303.

Referring to FIGS. 10A, 10B, and 16C, operation S14 of transferring the third inorganic light-emitting diode 2303 may include operation S143 of removing the third inorganic light-emitting diode 2303 from the third wafer WF3.

A temporary layer (not shown) may be formed between the third wafer WF3 and the third inorganic light-emitting diode 2303. The laser beam LA having a relatively high energy wavelength may be irradiated to the third wafer WF3 by an LLO process. At this time, the third inorganic light-emitting diode 2303 may be separated from the third wafer WF3 due to rapid melting and vaporization of the surface of the temporary layer (not shown).

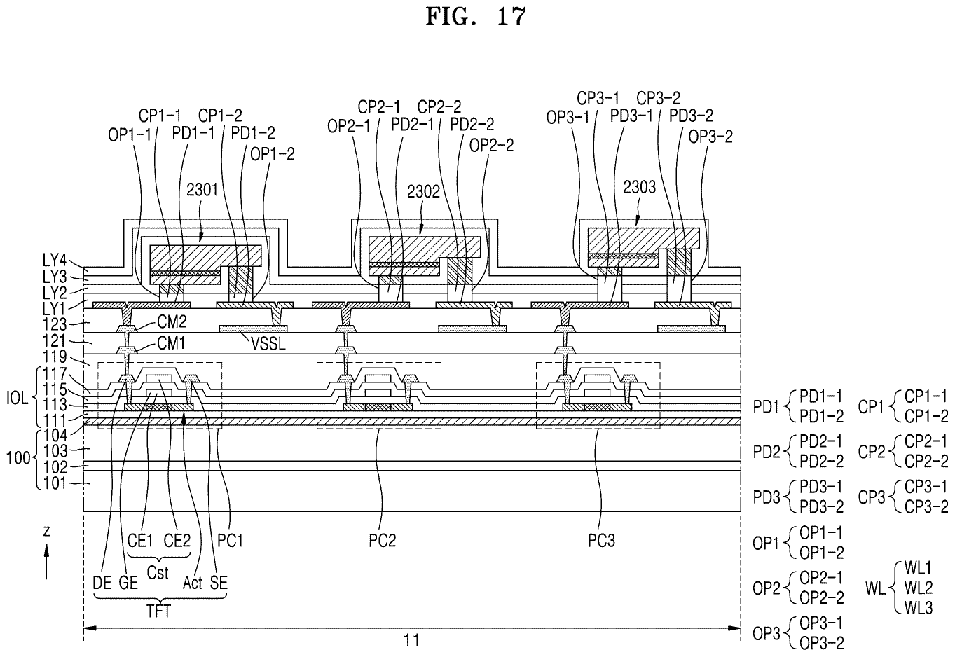

Referring to FIGS. 10A, 10B, and 17, the method 2 of manufacturing a display device may include operation S15 of disposing the fourth layer LY4 on the third layer LY3. The fourth layer LY4 may cover the third inorganic light-emitting diode 2303.

Referring to FIGS. 10A to 17, the first inorganic light-emitting diode 2301 may be disposed on the first wafer WF1, the second inorganic light-emitting diode 2302 may be disposed on the second wafer WF2, and the third inorganic light-emitting diode 2303 may be disposed on the third wafer WF3. At this time, the first inorganic light-emitting diode 2301, the second inorganic light-emitting diode 2302, and the third inorganic light-emitting diode 2303 may emit light of different colors. In addition, the first wafer WF1, the second wafer WF2, and the third wafer WF3 may be different from each other. That is, inorganic light-emitting diodes emitting light of different colors may be transferred through separate processes instead of being transferred simultaneously.

Accordingly, the first inorganic light-emitting diode 2301, the second inorganic light-emitting diode 2302, and the third inorganic light-emitting diode 2303, which emit light of different colors, may not be simultaneously disposed on one wafer. Accordingly, in the process of disposing the first inorganic light-emitting diode 2301, the second inorganic light-emitting diode 2302, and the third inorganic light-emitting diode 2303 on a wafer, a phenomenon of interference between inorganic light-emitting diodes emitting light of different colors may be reduced. Because the first inorganic light-emitting diode 2301, the second inorganic light-emitting diode 2302, and the third inorganic light-emitting diode 2303 are formed on a wafer through separate processes, the first inorganic light-emitting diode 2301, the second inorganic light-emitting diode 2302, and the third inorganic light-emitting diode 2303 may be precisely disposed on the first wafer WF1, the second wafer WF2, and the third wafer WF3, respectively.

The height of the first inorganic light-emitting diode 2301 from the substrate 100, the height of the second inorganic light-emitting diode 2302 from the substrate 100, and the height of the third inorganic light-emitting diode 2303 from the substrate 100 may sequentially increase. Because the first inorganic light-emitting diode 2301, the second inorganic light-emitting diode 2302, and the third inorganic light-emitting diode 2303 are formed on a wafer through separate processes, the first inorganic light-emitting diode 2301, the second inorganic light-emitting diode 2302, and the third inorganic light-emitting diode 2303 may be precisely transferred even when the heights of the first inorganic light-emitting diode 2301, the second inorganic light-emitting diode 2302, and the third inorganic light-emitting diode 2303 are different from each other.

In the process of transferring the second inorganic light-emitting diode 2302, the second layer LY2 may surround the first inorganic light-emitting diode 2301. Accordingly, in the process of transferring the second inorganic light-emitting diode 2302, a phenomenon of misalignment of the first inorganic light-emitting diode 2301, which has already been transferred to a designated position, may be reduced. In addition, in the process of transferring the third inorganic light-emitting diode 2303, the second layer LY2 and the third layer LY3 may surround the first inorganic light-emitting diode 2301, and the third layer LY3 may surround the second inorganic light-emitting diode 2302. Accordingly, in the process of transferring the third inorganic light-emitting diode 2303, a phenomenon of misalignment of the first inorganic light-emitting diode 2301 and the second inorganic light-emitting diode 2302, which have already been transferred to designated positions, may be reduced.

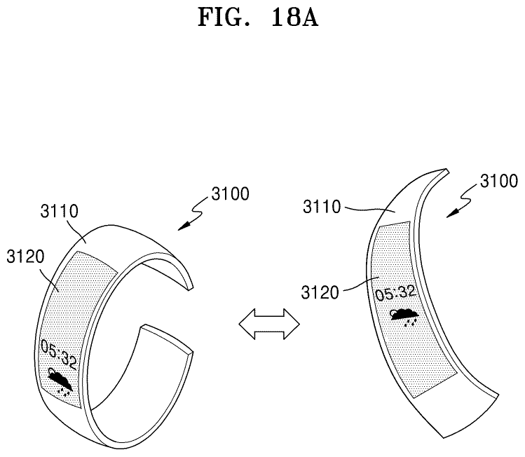

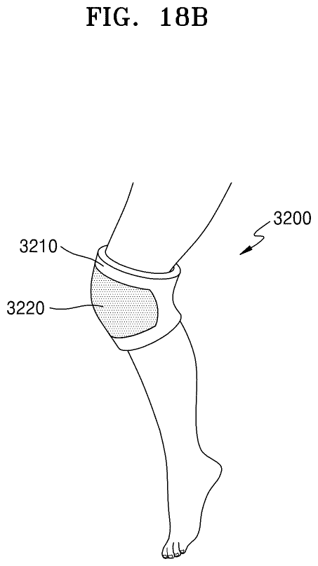

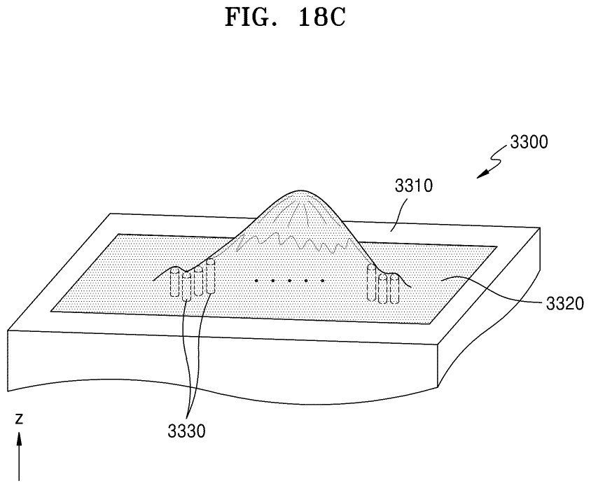

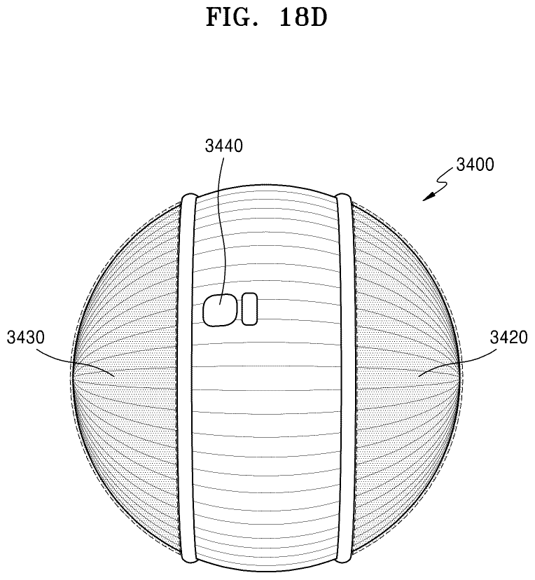

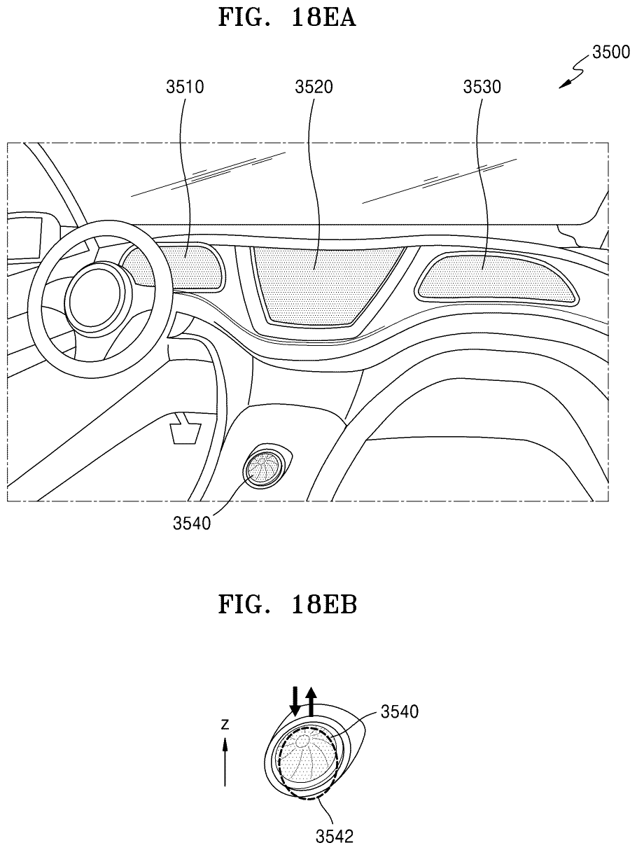

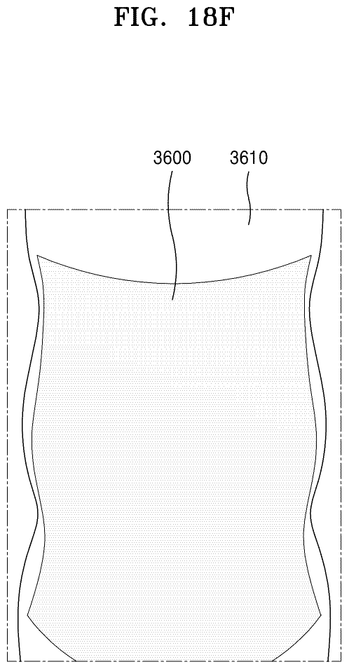

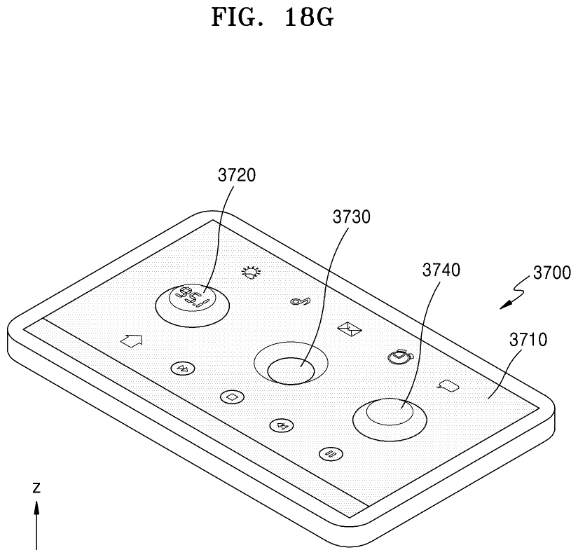

FIGS. 18A to 18G are schematic perspective views respectively showing embodiments of an electronic device including the display device 1 (refer to FIG. 1).

The display device 1, which is stretchable, in the embodiments described above may be used in various electronic devices that may provide images. Here, the electronic devices refer to devices that may provide predetermined images by electricity.

Referring to FIG. 18A, a stretchable display device in an embodiment may be used in a wearable electronic device 3100 which may be worn on a part of a user's body. The wearable electronic device 3100 may include a body portion 3110 and a display portion 3120 provided in the body portion 3110. A stretchable display device in embodiments may be used as the display portion 3120 of the wearable electronic device 3100. shown in FIG. 18A, the wearable electronic device 3100 may be transformable. In an embodiment, the wearable electronic device 3100 may be used as a smart watch or a smartphone depending on the user's choice.

FIG. 18B shows a medical electronic device 3200. In an embodiment, the medical electronic device 3200 may include a body portion 3210 and a light-emitting portion 3220. A stretchable display device in embodiments may be used as the light-emitting portion 3220 of the medical electronic device 3200. The light-emitting portion 3220 may emit light of a predetermined wavelength band (e.g., infrared light, visible light ray, or the like) to the body of a patient. In an embodiment, the body portion 3210 may include a stretchable fiber material and may have a structure that the light-emitting portion 3220 may be worn on the user's body.

FIG. 18C shows an educational electronic device 3300. In an embodiment, the educational electronic device 3300 may include a display portion 3320 provided in a frame 3310. The display portion 3320 may use a stretchable display device in embodiments. The display portion 3320 may provide images, such as a sea with waves, a mountain covered with snow, or a volcano with flowing lava, and at this time, the display portion 3320 may extend in a height direction (e.g., a z direction) by reflecting the height of the waves, the mountain, or the volcano. In some embodiments, a portion of the display portion 3320 may three-dimensionally show the movement of lava by sequentially changing the height along a direction in which the lava flows. The educational electronic device 3300 may include a plurality of pins (or stroke portions) 3330 arranged on the rear surface of the display portion 3320 so that the display portion 3320 may be stretched in the height direction. While the pins 3330 move along a third direction (e.g., a z direction or a -z direction), an image displayed on the display portion 3320 may be implemented to have a three-dimensional height. FIG. 18C shows the educational electronic device 3300, but the use is not limited as long as the device provides predetermined image information.

As shown in FIGS. 18A to 18C, an electronic device of which the shapes may be variable is described as the electronic device, but the disclosure is not limited thereto. As to be described below, a stretchable display device in embodiments may be used in an electronic device in which a portion capable of displaying images (e.g., a screen) is fixed.

FIG. 18D shows a robot 3400 as an electronic device. The robot 3400 may recognize movement or objects by a camera part 3440 and may display predetermined images through display portions 3420 and 3430. In some embodiments, as described above, because a stretchable display device in an embodiment may be stretched in various directions, the stretchable display device may be assembled into a body frame having a hemispherical shape, and accordingly, the robot 3400 may include the display portions 3420 and 3430 having hemispherical shapes.

FIG. 18EA shows a vehicle display device 3500 as an electronic device. The vehicle display device 3500 may include a cluster 3510, a center information display (“CID”) 3520, and/or a co-driver display 3530. Because a stretchable display device in an embodiment may be stretched in various directions, the stretchable display device may be used in the cluster 3510, the CID 3520, and/or the co-driver display 3530 regardless of the shape of the internal frame of the vehicle.

FIG. 18EA shows that the cluster 3510, the CID 3520, and the co-driver display are separated from each other, but the disclosure is not limited thereto. In another embodiment, two or more selected from the cluster 3510, the CID 3520, and the co-driver display may be integrally connected to each other.

In some embodiments, the vehicle display device 3500 may include a button 3540 that may display a predetermined image. Referring to the enlarged view of FIG. 18EB, the button 3540 having a hemispherical shape may include an object 3542 that provides the feeling using while moving in the z direction or the -z direction, and a stretchable display device disposed on the object 3542. In some embodiments, when the object 3542 has a three-dimensionally rounded surface, the stretchable display device may also have a three-dimensionally rounded surface.

FIG. 18F shows that an electronic device in an embodiment is an advertising or exhibiting electronic device 3600. In some embodiments, the advertising or exhibiting electronic device 3600 may be installed on a fixed structure 3610, such as a wall or pillar. When the structure 3610 includes an uneven surface as shown in FIG. 18F, the advertising or exhibiting electronic device 3600 may be disposed along the uneven surface of the structure 3610. In some embodiments, the advertising or exhibiting electronic device 3600 may be installed on the structure 3610 by a heat shrink film or the like.

FIG. 18G shows that an electronic device in an embodiment is a controller 3700. The controller 3700 may include an image-type button. In an embodiment, the controller 3700 may include first to third button areas 3720, 3730, and 3740 in which a partial area of a display portion 3710 protrudes in a z direction or a -z direction (or is depressed in the z direction), for example. In some embodiments, the first and third button areas 3720 and 3740 may protrude in the z direction, and the second button area 3730 may protrude in the -z direction (or may be depressed in the z direction).

By embodiments, the durability, visibility, and quality of a display device may be improved.

Effects of the disclosure are not limited to the effects mentioned above, and other effects not mentioned will be clearly understood by one of ordinary in the art from the description of the claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display device comprising:
a substrate;
a first pixel driving circuit part and a second pixel driving circuit part, disposed on the substrate and spaced apart from each other;
a first pad part disposed on the first pixel driving circuit part and electrically connected to the first pixel driving circuit part;
a second pad part disposed on the second pixel driving circuit part and electrically connected to the second pixel driving circuit part;
a first layer disposed on the first pad part and the second pad part and covering each of the first pad part and the second pad part;
a first inorganic light-emitting diode disposed on the first layer and electrically connected to the first pad part;
a second layer disposed on the first layer and covering the first inorganic light-emitting diode; and
a second inorganic light-emitting diode disposed on the second layer and electrically connected to the second pad part.

2. The display device of claim 1, further comprising a first connection part which is accommodated in a first connection opening and electrically connects the first pad part and the first inorganic light-emitting diode to each other, the first connection opening penetrating the first layer.

3. The display device of claim 1, further comprising a second connection part which is accommodated in a second connection opening and electrically connects the second pad part and the second inorganic light-emitting diode to each other, the second connection opening penetrating each of the first layer and the second layer.

4. The display device of claim 1, wherein a height of the second inorganic light-emitting diode from the substrate is greater than a height of the first inorganic light-emitting diode from the substrate.

5. The display device of claim 1, further comprising:
a third pixel driving circuit part disposed on the substrate;
a third pad part disposed on the third pixel driving circuit part and electrically connected to the third pixel driving circuit part;
a third layer disposed on the second layer and covering the second inorganic light-emitting diode; and
a third inorganic light-emitting diode disposed on the third layer and electrically connected to the third pad part.

6. The display device of claim 5, further comprising a third connection part which is accommodated in a third connection opening and electrically connects the third pad part and the third inorganic light-emitting diode to each other, the third connection opening penetrating each of the first layer, the second layer, and the third layer.

7. The display device of claim 5, further comprising a fourth layer disposed on the third layer and covering the third inorganic light-emitting diode.

8. The display device of claim 5, wherein a height of the third inorganic light-emitting diode from the substrate is greater than a height of the second inorganic light-emitting diode from the substrate.

9. The display device of claim 1, wherein the first inorganic light-emitting diode and the second inorganic light-emitting diode emit light of different colors from each other.

10. An electronic device comprising:
a substrate;
a first pixel driving circuit part, a second pixel driving circuit part, and a third pixel driving circuit part, which are disposed on the substrate and spaced apart from each other;
a first pad part disposed on the first pixel driving circuit part and electrically connected to the first pixel driving circuit part;
a second pad part disposed on the second pixel driving circuit part and electrically connected to the second pixel driving circuit part;
a third pad part disposed on the third pixel driving circuit part and electrically connected to the third pixel driving circuit part;
a first layer disposed on the first pad part, the second pad part, and the third pad part to cover each of the first pad part, the second pad part, and the third pad part;
a first inorganic light-emitting diode disposed on the first layer and electrically connected to the first pad part;
a second layer disposed on the first layer and covering the first inorganic light-emitting diode;
a second inorganic light-emitting diode disposed on the second layer and electrically connected to the second pad part;
a third layer disposed on the second layer and covering the second inorganic light-emitting diode; and
a third inorganic light-emitting diode disposed on the third layer and electrically connected to the third pad part.

11. A method of manufacturing a display device, the method comprising:
disposing a first pixel driving circuit part and a second pixel driving circuit part on a substrate;
disposing a first pad part on the first pixel driving circuit part and electrically connecting the first pixel driving circuit to the first pixel driving circuit part;
disposing a second pad part on the second pixel driving circuit part and electrically connected to the second pixel driving circuit part;
disposing a first layer on the first pad part and the second pad part so that the first layer covers each of the first pad part and the second pad part;
transferring a first inorganic light-emitting diode onto the first pad part;
disposing a second layer on the first layer so that the second layer covers the first inorganic light-emitting diode; and
transferring a second inorganic light-emitting diode onto the second pad part.

12. The method of claim 11, wherein the transferring the first inorganic light-emitting diode comprises:
disposing the first inorganic light-emitting diode on a first wafer;
disposing the first inorganic light-emitting diode on the first layer so that the first inorganic light-emitting diode is electrically connected to the first pad part; and
removing the first wafer from the first inorganic light-emitting diode.

13. The method of claim 12, wherein the transferring the second inorganic light-emitting diode comprises:
disposing the second inorganic light-emitting diode on a second wafer;
disposing the second inorganic light-emitting diode on the second layer so that the second inorganic light-emitting diode is electrically connected to the second pad part; and
removing the second wafer from the second inorganic light-emitting diode.

14. The method of claim 13, wherein the first wafer is different from the second wafer.

15. The method of claim 11, further comprising:
defining a first connection opening in the first layer so that the first connection opening exposes the first pad part; and
disposing a first connection part comprising a conductive material, in the first connection opening, wherein
the first connection part electrically connects the first pad part and the first inorganic light-emitting diode to each other.

16. The method of claim 11, further comprising defining a second connection opening in the first layer and the second layer so that the second connection opening exposes the second pad part; and
disposing a second connection part comprising a conductive material, in the second connection opening, wherein
the second connection part electrically connects the second pad part and the second inorganic light-emitting diode to each other.

17. The method of claim 11, further comprising:
disposing a third pixel driving circuit part on the substrate;
disposing a third pad part on the third pixel driving circuit part and electrically connecting the third pad part to the third pixel driving circuit part;
disposing a third layer on the second layer so that the third layer covers the second inorganic light-emitting diode; and
transferring a third inorganic light-emitting diode onto the third pad part;
wherein the transferring the third inorganic light-emitting diode comprises:
disposing the third inorganic light-emitting diode on a third wafer;
disposing the third inorganic light-emitting diode on the third layer so that the third inorganic light-emitting diode is electrically connected to the third pad part; and
removing the third inorganic light-emitting diode from the third wafer.

18. The method of claim 17, further comprising disposing a fourth layer on the third layer so that the fourth layer covers the third inorganic light-emitting diode.

19. The method of claim 17, further comprising:
defining a third connection opening in the first layer, the second layer, and the third layer so that the third connection opening exposes the third pad part; and
disposing a third connection part comprising a conductive material, in the third connection opening,
wherein the third connection part electrically connects the third pad part and the third inorganic light-emitting diode to each other.

20. The method of claim 17, wherein a height of the first inorganic light-emitting diode from the substrate, a height of the second inorganic light-emitting diode from the substrate, and a height of the third inorganic light-emitting diode from the substrate sequentially increase.
